(19) United States
(12) Patent Application Publication
(10) Pub. No.: US 2016/0007484 A1
(43) Pub. Date: Jan. 7, 2016

(54) Bag computer display panel improvements

(71) Applicant: Charles Augustus Daley, III, Rawai (TH)

(72) Inventor: Charles Augustus Daley, III, Rawai (TH)

(21) Appl. No.: 14/756,489

(22) Filed: Sep. 10, 2015

Related U.S. Application Data
(63) Continuation of application No. 13/987,618, filed on Aug. 15, 2013.

(51) Int. Cl. H05K 5/00; H05K 5/02

(52) U.S. Cl. CPC H05K 5/0017; H05K 5/0086; H05K 5/0247

(57) ABSTRACT

Disclosed are improvements on a display panel mounted to a bag. For a display panel mounted in a pocket and with a retainer for angle holding capability, protective spacers may be provided. To hold a vertical operating position, alternative plug and socket, sliding and pivoting prop and pivoting prop mounted to a fixed prop may be provided. A bag made for display panel mounting may include an attachment area and including a display panel to bag front prop is disclosed. For display panels mounted with right and left free sections, a loop of material may serve as the free sections for quick mounting and dismounting. An electrical connection, specialized holder and removable display panel including free sections are also disclosed. The display panel may be mounted to the bag with a two panel arrangement where a cover folds over the display panel in a way reminiscent of folding portable clock.

### CROSS-REFERENCE TO RELATED APPLICATIONS

This application is a Continuation application of copending patent application Ser. No. 13/987,618 filed on Aug. 15, 2013, the disclosure of this U.S. patent application is incorporated herein by reference.

### TECHNICAL FIELD

The present invention relates to a computer display designed for mobile use.

### BACKGROUND OF THE INVENTION

In several patents, including U.S. Pat. No. 7,889,496, the idea of a computer display panel pivotally mounted to the outside of a bag was developed. The idea of a display panel pivotally attached to the bag by a single edge U.S. Pat. No. 7,894,179 was also presented.

Of course, improvements to this arrangement may be envisioned. For example, the display panel may be mounted using a display panel clamped to a flexible fabric flap application Ser. No. 13/137,520 on the bag. This may then lead to a means to support such an arrangement at various viewing angles without using the hands U.S. Pat. No. 7,889,496.

The idea of a display panel mounted to the bag in a way where the display panel pulls vertically out of a pocket and then pivots into a viewing position was also presented application Ser. No. 13/135,446. This may lead to means to protect the display from scratching.

The idea of viewing the display from the back and over the top of the bag in order to prop the display higher and farther away from the operator/wearer/s body was also presented in application Ser. No. 13/137,467. This may lead to the need to a means to hold the display panel at various vertical angles to make the display face the operator.

The idea of having the display panel pivotally mounted to the bag using right and left sections of material to allow the display panel to be held at angle without using a prop was also presented in application Ser. No. 12/927,884. This may lead to ideas of varied movements of the panel and various simplified means to apply this idea.

The idea of using an intermediate panel between the display panel and the bag front was also presented application Ser. Nos. 12/216,650 and 11/796,920. This may lead to the possibility of a fold out display panel operating in a way similar to the way folding travel clock works.

These various improvements to the bag mounted display panel are presented in this application.

### BRIEF DESCRIPTION OF THE INVENTION

The invention presented is a group of improvements to a display panel mounted to a bag. These improvements represent embodiments of the invention.

In one embodiment, the display panel may be provided with rails on the display side of the display panel for the purpose of holding the panel away from the object within it is stored. For example, the rails may protect the display by keeping it from touching a pocket in which it is stored.

In a second embodiment, the display panel may be fitted with t holder on its bottom/proximal/attachment edge which matches a complementary holder on the bag. Such a holder can hold the display panel in a vertical position in the situation where the display panel is held in a pocket which may not be substantial enough to support the display panel.

In a third embodiment, the display panel may be provided with a prop which slides parallel to the plane of the display panel. When deployed, this prop can hold the display panel in a vertical operating position. Further, the prop may have a pivoting arm which, when rotated into position, can support the display panel at a viewing angle between the top wall and display panel that is less than 90 degrees. This angling of the display panel may be of advantage when the operator is viewing the display in a back to front direction over the top of the bag. The bag may be provided with fittings matching the prop end to temporarily attach the prop end to the bag front and better hold the display panel angle.

In a fourth embodiment, a display panel already supplied with a prop or extension fixed to its attachment edge may be further provides with a second vertical operating position prop mounted to the fixed prop or extension. The vertical operating position prop may be pivotally mounted to the fixed prop so it may be pivoted into use when the operator desires to adjust the viewing angle when he is viewing the display in a back to front direction over the top of the bag.

In a fifth embodiment, a folding display panel mounting assembly is used to attach the display panel to the bag and provide a prop at the same time. The assembly is a length of material with the components; 1) removable or permanently attachment to the bag, 2) an attachment for the display panel and 3) a prop. A variety of attachments are described.

In a sixth embodiment, the display panel is attached to the bag with right and left free sections and arranged to have the display on the display panel's display facing inward toward the bag front wall. The back side of the display panel may have a protecting coating. The bag may include mounting components which may be attached to the bag separately or may be combined into a single mounting assembly attached to the bag front wall. A free section may include an electrical connection.

In a seventh embodiment, the free sections may be formed by a simple loop of material, such as a strap, attached to the bag front wall. The display panel would be adapted in various ways to hold the loop on its back side or side edges. The bag may include mounting assembly components and may be coordinated with a computing unit panel mounted to the inside surface of the bag front wall to support the mounting assembly on the outside of the bag front wall.

An eighth arrangement shows that the display panel may include pivoting free sections adapted to attach to a matching bag.

In a ninth embodiment, the display panel is pivotally attached by its proximal edge to a cover which is pivotally attached to the bag front wall and serves as an intermediate panel between the display panel and bag front. These two panels, arranged is a pivoting series, fold against the bag front wall so that, in storage position, the display panel is stored between the cover and the bag front wall. When in operating position, the display panel's display is facing up and the cover supports the display panel by its distal edge. The display panel may be removably attached. Springs, latches and panel angle restraints may be included to facilitate achieving and holding the operating position. The bag may include a computing unit panel mounted to the inside surface of the bag front wall to support the display panel holder on the outside of the bag front wall.

### BRIEF DESCRIPTION OF THE SEVERAL VIEWS OF THE DRAWINGS

FIG. 1A The bag computer is shown here with the cover and display and showing basic components.

FIG. 1B the bag computer has the display panel in an operating position and showing various components and orientations.

FIG. 1C This is a back side view of the bag computer.

FIG. 1D Here, the display panel is in a vertical operating position and showing various components and orientations.

FIG. 1E This is a drawing of the “plane” of the display panel in 1B.

FIG. 2A This is a front view of the display panel.

FIG. 2B This is a left side edge view of the display panel.

FIG. 2C This is a view of the back side of the display panel.

FIG. 3 This is a front view of the bag computer with the display panel stored in a holder on the front wall.

FIG. 4A This is a cross section side view of the bag computer at a/b of FIG. 3 with the display panel stored in a holder on the front wall.

FIG. 4B This is a magnified view of the details of the display panel in FIG. 4A.

FIG. 5 This is a cross section top view of the bag computer at c/d of FIG. 4A with the display panel stored in a holder on the front wall.

FIG. 6A This is a cross section side view of the bag computer at a/b of FIG. 3 with the display panel in a vertical operating position on the front wall.

FIG. 6B This is a magnified view of the details of the display panel attachment to the bag shown in FIG. 6A.

FIG. 7A This is a cross section side view of the bag computer at a/b of FIG. 3 with the display panel in an operating position approximately perpendicular to the front wall.

FIG. 7B This is a magnified view of the details of the display panel attachment to the bag shown in FIG. 6A and including propping details.

FIG. 8 This is a front view of the display panel showing the positioning of a prop bar.

FIG. 9 This is an angled prop bar.

FIG. 10 This is an attachment edge view of the display panel showing the pivoting of the prop bar.

FIG. 11 This is a right side view of the display panel in a vertical operating position with the prop bar not deployed.

FIG. 12 This is a right side view of the display panel in a vertical operating position with the prop bar in a deployed position.

FIG. 13 This is a right side view of the display panel in a vertical operating position with the prop bar in a deployed position and pivoted so the pivoting arm part changes the angle of the display panel relative to the bag front wall.

FIG. 14 This is a right side view of the display panel in a vertical operating position with the prop bar in a deployed position and pivoted so the pivoting arm part is touching the bag front. The prop bar is slid along the sliding axis to further alter the display panel angle relative to the bag front.

FIG. 15 This is a front view of the display panel showing the position of a vertical operating position prop on the fixed prop/extension.

FIG. 16A This is a cross section right side edge view of the display panel at a/b of FIG. 15 with the vertical operating position prop in a stored position.

FIG. 16B This is a cross section right side edge view of the display panel at a/b of FIG. 15 with the vertical operating position prop in a deployed position.

FIG. 17A This is a cross section right side edge view of the display panel at a/b of FIG. 15 now attached to the bag to show its operation. The vertical operating position prop is in a deployed position.

FIG. 17B This is the same arrangement of prop parts as FIG. 17A but showing how the viewing angle can be adjusted.

FIG. 18 This is a front view of the display panel showing the position of a vertical operating position prop on the fixed prop/extension. The pivoting arrangement is different from FIG. 15.

FIG. 19A This is a cross section right side edge view of the display panel at a/b of FIG. 18 with the vertical operating position prop in a stored position.

FIG. 19B This is a cross section right side edge view of the display panel at a/b of FIG. 18 with the vertical operating position prop in a deployed position.

FIG. 20A This is a cross section right side edge view of the display panel at a/b of FIG. 18 now attached to the bag to show its operation. The vertical operating position prop is in a deployed position.

FIG. 20B This is the same arrangement of prop parts as FIG. 20A but showing how the viewing angle can be adjusted.

FIG. 21 This is a front view of the display panel showing the position of a vertical operating position prop on the fixed prop/extension. The pivoting arrangement is different from FIG. 15 or FIG. 18.

FIG. 22A This is a cross section right side edge view of the display panel at a/b of FIG. 21 with the vertical operating position prop in a stored position.

FIG. 22B This is a cross section right side edge view of the display panel at a/b of FIG. 21 with the vertical operating position prop in a deployed position.

FIG. 23A This is a cross section right side edge view of the display panel at a/b of FIG. 21 now attached to the bag to show its operation. The vertical operating position prop is in a deployed position.

FIG. 23B This is the same arrangement of prop parts as FIG. 23A but showing how the viewing angle can be adjusted.

FIG. 24 This is a front view of the display panel showing the position of a vertical operating position prop on the fixed prop/extension. The pivoting arrangement is different from FIG. 15, FIG. 18 or FIG. 21.

FIG. 25A This is a cross section right side edge view of the display panel at a/b of FIG. 24 with the vertical operating position prop in a stored position.

FIG. 25B This is a cross section right side edge view of the display panel at a/b of FIG. 24 with the vertical operating position prop in a deployed position.

FIG. 26A This is a cross section right side edge view of the display panel at a/b of FIG. 24 now attached to the bag to show its operation. The vertical operating position prop is in a deployed position.

FIG. 26B This is the same arrangement of prop parts as FIG. 26A but showing how the viewing angle can be adjusted.

FIG. 27 This is a front view of the display panel showing the position of a vertical operating position prop on the fixed prop/extension. The pivoting arrangement is different from FIG. 15, FIG. 18, FIG. 21 or FIG. 24.

FIG. 28A This is a cross section right side edge view of the display panel at a/b of FIG. 27 with the vertical operating position prop in a stored position.

FIG. 28B This is a cross section right side edge view of the display panel at a/b of FIG. 27 with the vertical operating position prop in a deployed position.

FIG. 29A This is a cross section right side edge view of the display panel at a/b of FIG. 27 now attached to the bag to show its operation. The vertical operating position prop is in a deployed position.

FIG. 29B This is the same arrangement of prop parts as FIG. 29A but showing how the viewing angle can be adjusted.

FIG. 30 This is a right side view of the display panel mounted to the bag and including attachment on the bag front to match the prop.

FIG. 31 This is a front view of the display panel mounted to the bag and including attachment on the bag front to match the prop.

FIG. 32 This is a front view of the display panel showing the position of two vertical operating position prop on a right and a left fixed prop/extensions.

FIG. 33A This is a cross section right side edge view of the display panel at a/b of FIG. 32 with the vertical operating position props in a stored position.

FIG. 33B This is a cross section right side edge view of the display panel at a/b of FIG. 32 with the vertical operating position props in a deployed position.

FIG. 34A This is a cross section right side edge view of the display panel at a/b of FIG. 32 now attached to the bag to show its operation. The vertical operating position props are in a deployed position.

FIG. 34B This is the same arrangement of prop parts as FIG. 34A but showing how the viewing angle can be adjusted.

FIG. 35 This is a front view of the display panel showing the position of two vertical operating position prop on a right and a left fixed prop/extensions. The pivoting arrangement is different from FIG. 32.

FIG. 36A This is a cross section right side edge view of the display panel at a/b of FIG. 35 with the vertical operating position props in a stored position.

FIG. 36B This is a cross section right side edge view of the display panel at a/b of FIG. 35 with the vertical operating position props in a deployed position.

FIG. 37A This is a cross section right side edge view of the display panel at a/b of FIG. 32 now attached to the bag to show its operation. The vertical operating position props are in a deployed position.

FIG. 37B This is the same arrangement of prop parts as FIG. 37A but showing how the viewing angle can be adjusted.

FIG. 38 This is a drawing of a display panel back side including a mounting assembly attachment area.

FIG. 39 This is a drawing of a mounting assembly including an attachment area.

FIG. 40 This is a display panel in position to attach to a mounting assembly.

FIG. 41 This is a display panel mounting assembly in position to attach to the display panel.

FIG. 42A This shows the folding display panel mounting assembly with the assembly removable attached to the bag.

FIG. 42B This shows the folding display panel mounting assembly with the assembly pivotally and permanently attached to the bag.

FIG. 42C This shows the folding display panel mounting assembly with the assembly attached to the display panel. The display panel removably attaches the display panel and assembly to the bag.

FIG. 43 This is the display panel mounting assembly including an electrical connection.

FIG. 44 This is the display panel mounting assembly designed to grip the bag front.

FIG. 45 This is the display panel mounting assembly including a cut out.

FIG. 46 This is the display panel mounting assembly made of wire.

FIG. 47 This is the folding display panel mounting assembly (without display panel attached) pivotally attached to the bag in a storage position.

FIG. 48 This is the folding display panel mounting assembly (without display panel attached) pivotally attached to the bag in an operating position with the prop deployed.

FIG. 49 This is the display panel mounting assembly (without display panel attached) pivotally attached to the bag in a vertical operating position.

FIG. 50 This is the folding display panel mounting assembly (with display panel attached) pivotally attached to the bag in a storage position.

FIG. 51 This is the folding display panel mounting assembly (with display panel attached) pivotally attached to the bag in an operating position with the prop deployed.

FIG. 52 This is the display panel mounting assembly (with display panel attached) pivotally attached to the bag in a vertical operating position.

FIG. 53 This is the folding display panel mounting assembly mounted near the center of the bag front. The display panel is here folded upward into a storage position.

FIG. 54 This is the folding display panel mounting assembly mounted near the center of the bag front. The display panel is here folded downward into an operating position and viewable to the operator/bag wearer.

FIG. 55 This is a bag with a display panel mounted to the front with its display facing toward the bag front wall.

FIG. 56A This is the bag of FIG. 52 with the display panel deployed using free sections to the right and left sides of the display panel.

FIG. 56B This is a magnified view of the FIG. 53A display panel to bag attachment area showing free section details.

FIG. 57 This is a bag with a display panel mounted to the front with its display facing toward the bag front wall and including display panel holding assembly.

FIG. 58A This is the bag of FIG. 54 with the display panel deployed using free sections to the right and left sides of the display panel and including the components of the display panel holding assembly.

FIG. 58B This is a magnified view of the FIG. 55A display panel to bag attachment area showing free section details.

FIG. 58C This is a magnified view of the FIG. 55A display panel to bag attachment area showing a means for electrical connection as part of one free section.

FIG. 59A This is a bag with a display panel mounted to the front with its display facing toward the bag front wall and including display panel holder.

FIG. 59B This is the bag of FIG. 56A with the display panel deployed using free sections to the right and left sides of the display panel and including the components of the display panel holder.

FIG. 59C This is the display panel holder shown separate from the bag and display panel and showing it's parts and including a back plate.

FIG. 59D This view shows the back side to the display panel holder.

FIG. 60 This is the mounting strap used as the display panel mounting free sections.

FIG. 61 This is a bag with a display panel mounting assembly and mounting strap attached to the bag as a loop but without the display panel mounted to the bag.

FIG. 62A This is a bag with a display panel mounting assembly and mounting strap with the display panel mounted to the bag and in storage position.

FIG. 62B This is the display panel separated from the bag and showing details of the back side of the display panel.

FIG. 62C This is the display panel separated from the bag and showing details of the front side of the display panel.

FIG. 63 This is a bag with a display panel mounting assembly and mounting strap with the display panel mounted to the bag and in an operating position.

FIG. 64A This is a magnified view of an attachment area of the mounting strap on the display panel. Detail 1.

FIG. 64B This is a magnified view of an attachment area of the mounting strap on the display panel. Detail 2.

FIG. 64C This is a magnified view of an attachment area of the mounting strap on the display panel. Detail 3.

FIG. 64D This is a magnified view of an attachment area of the mounting strap on the display panel. Detail 4.

FIG. 64E This is a magnified view of an attachment area of the mounting strap on the display panel. Detail 5.

FIG. 64F This is a magnified view of an attachment area of the mounting strap on the display panel. Detail 6.

FIG. 65A This is an exploded view of a bag with a display panel mounting assembly and mounting strap with the display panel mounted to the bag and in storage position.

FIG. 65B This is a view of the inside surface of the bag front wall shown in 62A and including a computing unit panel.

FIG. 65C This is a view of the inside surface of the bag front wall shown in 62A and including a rigid panel.

FIG. 66 This is a bag with the display panel mounted to its front and in storage position. The free sections are pivotally fixed to the display panel and the first pivoting attachment is removably attached to the bag.

FIG. 67 This is a bag with the display panel mounted to its front and in operating position. The free sections are pivotally fixed to the display panel and the first pivoting attachment is removably attached to the bag.

FIG. 68 This view shows the display panel removed from the bag and including free sections pivotally fixed to the display panel.

FIG. 69A This is a bag with a two panel cover/display unit attached to the front wall and in a storage position.

FIG. 69B This is a bag with a two panel cover/display unit attached to the front wall and open in an operating position.

FIG. 69C This is a two panel cover/display unit separate from the bag and open in an operating position.

FIG. 69D This is two panel cover/display unit with the display panel in an operating position and the cover in a closed storage position.

FIG. 70 This is front view of a bag with a two panel cover/display unit attached to the front wall and in a storage position.

FIG. 71A This is a right side cross section view at A/B of the bag in FIG. 70. It shows the bag with a two panel cover/display unit attached to the front wall and in a storage position.

FIG. 71B This is a right side cross section view at A/B of the bag in FIG. 70. It shows the bag with a two panel cover/display unit attached to the front wall and opened half way into an operating position.

FIG. 71C This is a right side cross section view at A/B of the bag in FIG. 70. It shows the bag with a two panel cover/display unit attached to the front wall and in an operating position.

FIG. 72 This is an exploded view showing the various components of a bag with a two panel cover/display unit attached to the front wall and in an operating position.

FIG. 73A This figure shows the display panel and cover may be removable from each other.

FIG. 73B This figure shows the display panel clasp of FIG. 73A where its attachment to the cover is a clamp and where the clasp includes a display panel prop.

FIG. 74A This figure shows the display panel pivoted on the cover so that it is inverted and the display panel back side, including a display, is facing upward toward the operator.

FIG. 74B This figure shows the display panel that the inverted display panel may now have controls on the front side.

FIG. 75 This figure shows the cover/display assembly mounted to bag in storage position and covered with a second cover.

FIG. 76 This figure shows the cover/display assembly mounted to bag in an operating position with the display and a keyboard ready for use.

FIG. 77 This figure shows an exploded view of the cover/display assembly and bag and the various components.

FIG. 78 This figure shows a bag designed for the cover/display assembly (dismounted) and including a storage pocket and cover retraining means combination.

### DETAILED DESCRIPTION OF THE INVENTION

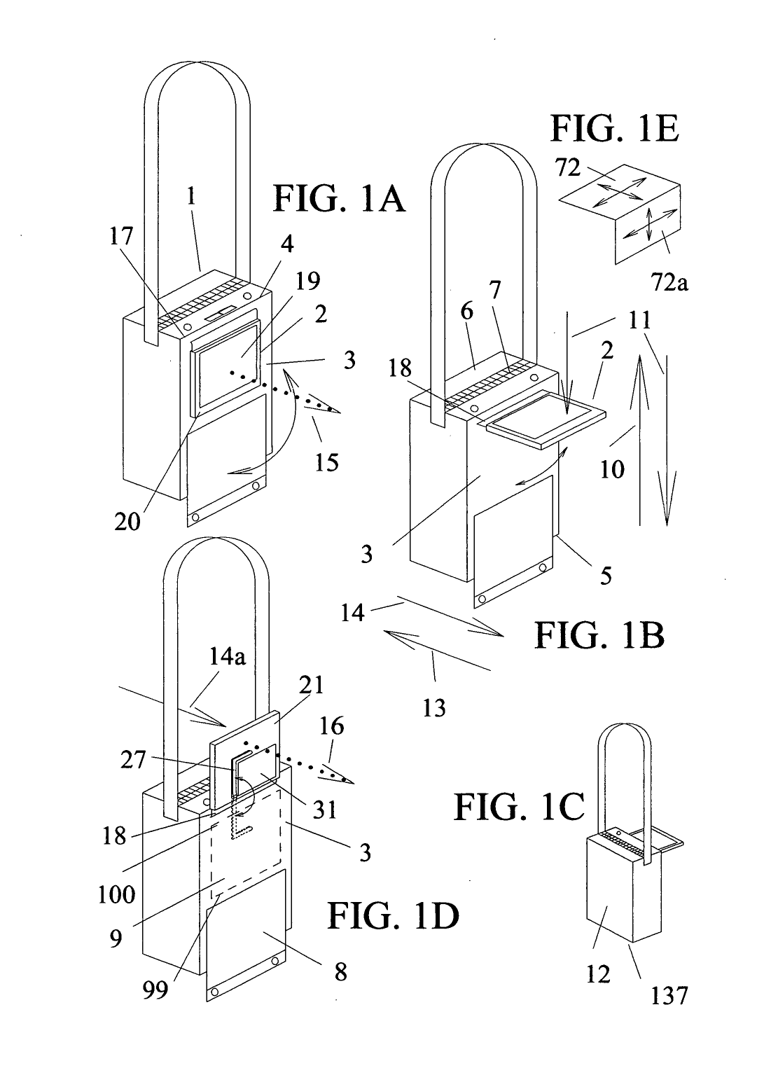

FIGS. 1A, 1B, 1C, 1D and 1E show a bag computer including a bag 1 and a display panel 2. The bag may have a front wall 3 (here showing the outside surface) which may have a top edge 4 and a bottom edge 5. At the top of the bag there may be a top wall 6 which may include an opening 7 for accessing the bag interior (here shown with a zipper closure). The bag may include a cover flap 8 pivotally attached to the bag front and configured to pivot and cover the computer equipment storage area 9 (shown in dashed line) where the display panel is found when in storage position. The computer equipment storage area includes a top end 100 and a bottom end 99.

There may be orientations relative to the bag. The bag has an upward 10 orientation direction which is toward the top of the bag, and a downward 11 orientation direction. The bag may include a back wall 12 and a bottom 137 (shown in FIG. 1C) and the bag may include an orientation of front to back direction 13 or back to front direction 14. There is a plane 72 (FIG. 1E) called the “plane of the display panel” wherein this plane is a surface parallel to the display panel in all directions. Similarly, there is a “plane of the bag front wall” 72a.

There may also be an orientation relative to the display panel. There may be an away from the display panel front side 20 direction 15 orientation (FIG. 1A, dotted arrow) and there may be an away from the display panel back side 21 direction 16 orientation (FIG. 1D, dotted arrow). This orientation applies no matter what position the display panel may be in. FIG. 1D also shows that a prop 27 may be included on the display panel back side and this prop may pivot. The prop may be positioned on the display panel back, such as off set to one side edge of the display panel, and shaped so that a touch pad 31 may be increased in size.

The bag may also include a display panel 2 pivotally attached to the bag near the junction 17 of the top and front walls and the top edge of the front wall. The display panel may be attached to the bag using a pivoting display panel attachment means 18 such as a pivoting computer equipment mount, which removably and pivotally attaches the display panel to the bag.

The display panel includes a display 19 and may be moved into a storage position (shown in FIG. 1A) in the computer equipment storage area 9 next to and approximately parallel to the bag front wall. From that position the display panel may be pivoted into an operating position (shown in FIGS. 1B, 1C, and 1D) with the display facing and visible to the operator/wearer of the bag (for example with the operator viewing downward direction 11 in FIG. 1B). The operating position may be vertical operating position (shown in FIG. 1D) with the display panel plane approximately parallel to the bag front wall and the display viewable in a back to front direction 14a over the bag top wall. The vertical operating position may vary in angle relative to the bag front. Its purpose is to view the display from an angle extending over the bag top or top wall. This position is useful for using the bag to elevate the display from a surface it rests on, such as the lap or the stomach. In this way viewing of the display may be facilitated.

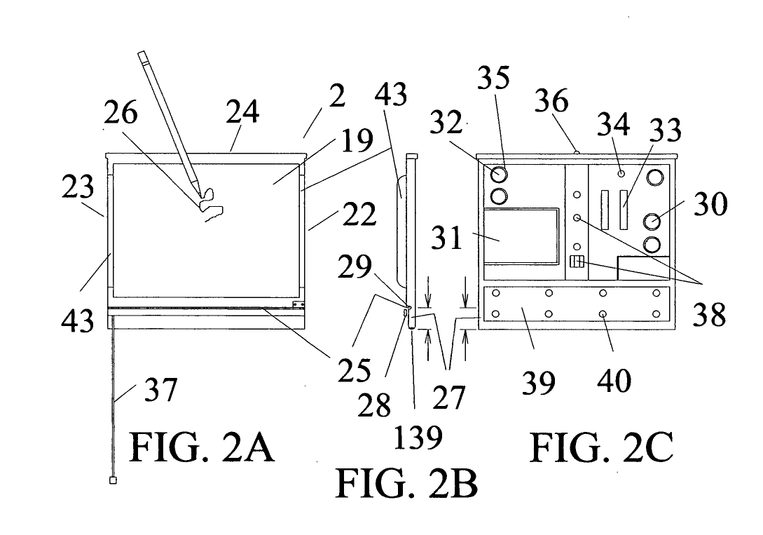

Shown in FIGS. 2A, 2B, and 2C, the display panel 2 may be panel like with a front side (shown in FIG. 2A) which may include a display 19 and/or controls, a back side (shown in FIG. 2C), a right side edge 22, a left side edge 23, a distal edge 24 and a proximal attachment edge 25. The display may include a touch screen 26 (shown with stylus writing). The display panel may include one or more props, legs or extension 27 for assisting in holding the display panel at various operating positions relative to the bag front. The extension may be fixed to the display panel and may be immovable relative to the display panel. There may be more than one prop or there may be one continuous prop along the proximal attachment edge of the display panel. In the case of one continuous prop, the prop may obscure the attachment edge. When thus obscured, the attachment edge is defined by the place on the display panel where the attachment means to the bag is attached to the display panel.

The attachment edge may also be called an attachment axis in the case where the connection or attachment to the bag pivots where it attaches to the DP. This is the case where the attachment to the bag is at the right side edge and left side edge of the display panel with the attachment axis extending through the display panel between the two side attachment points.

Shown in side view FIG. 2B, the attachment edge may include a means of attachment such as one or more clamps, jaws 28, channels 29, tracks, rails, snaps, hooks, hook and loop or other means to connect the display panel to the bag. Also shown is a side view of protective spacers 43, here shown as rails, intended to keep the display from rubbing and being damaged in storage or while moving into and out of storage. The prop or extension of the display panel may include a gripping feature 139, such as grooves, teeth, projections, contact surface matching features, sockets or rubberized-like material, designed to help the extension temporarily adhere to the bag front or to a contact surface. In FIG. 2C, the back side of the display panel, the side of the display panel opposite the display, may include a display, controls 30 such as one or more touch pads 31, buttons 32, slides 33, switches 34 or other means to operate the display or a computer attached to it. The back side may include a display. The controls may include one or more finger guides 35. The display panel may include an input/output device such as a camera 36, antenna or communicator. The display panel may include other electronics such as computing unit, input/output devices, batteries, telephone, radio communication, etc. The display panel may include one or more electrical connection 37 to connect it with external electronics. The display panel may include display panel prop fixtures 38 for permanently or temporarily holding a display panel prop which holds the display panel at angles relative to the bag front. If the display panel is attached to the bag or a prop by its back side, the display panel may include an attachment area 39 on its back side which may include attachments 40 such as snaps, clamp, hook and loop or other means.

Several arrangements to improvement the bag computer apparatus to support the display panel in the vertical operating position may be described.

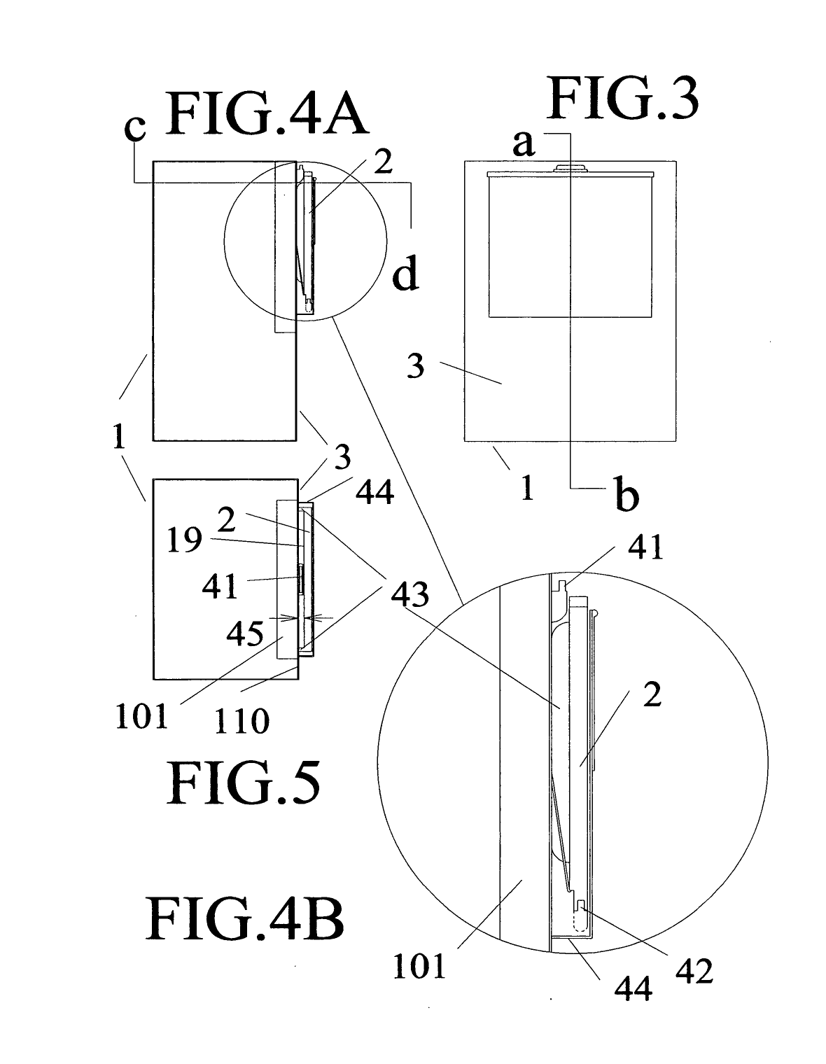

In one arrangement, shown in storage position in FIG. 3 (front view), FIG. 4A (side view at cross section a-b in FIG. 3) and FIG. 4B (magnification), the display panel 2 is in storage position in a holder 44 on the outside surface of the bag front wall 3. The display panel may include protective spacers 43, such as rails or knobs on the display panel front side or edges, extending between the display panel and the bag front when the display panel is in a storage position and intended to keep the display from rubbing and being damaged in storage or while moving into and out of storage. The display panel and bag 1 may be fitted with a vertical operating position support fixture including matching parts, bag prop part 41 and display panel prop part 42, to support the display panel in the vertical operating position. The matching parts may be socket and plug, hook and loop, hook and bail or other means.

Shown in top view FIG. 5 (at cross section c-d in FIG. 4A), the matching prop part 41 on the bag may be positioned between protective spacers 43, here shown as rails, on the display panel 2 or on the display panel holder 44. The protective spacer (rails) provide a space 45 between the bag and display 19 so that the display is not damaged by rubbing bag parts while in a storage position and so the prop part 41 does not interfere with the removal and replacement of the display panel in a holder on the bag front. Also shown is a computing unit panel 101 attached to the inside surface 110 of the bag front wall. This panel can assist in making rigid and flattening the bag front wall and protect the display from rubbing and scratching caused by the bag. The computing unit panel may also include telecommunications, radio communication, batteries, electrical connections and/or other electrical equipment.

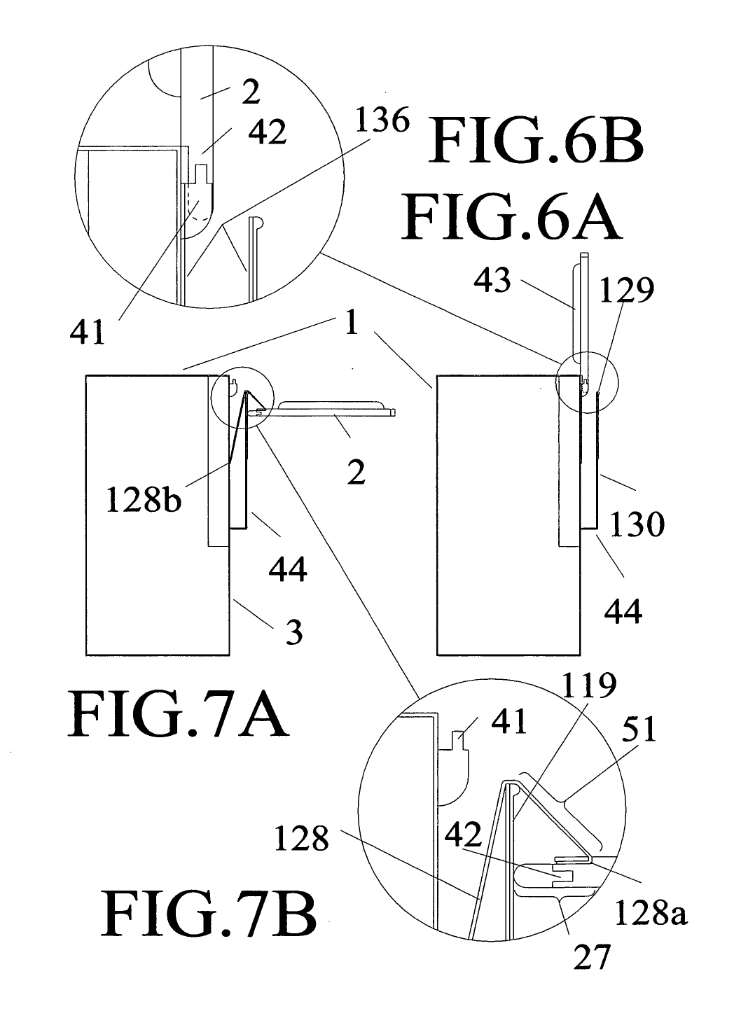

Shown in FIG. 6A (shown at cross section a-b in FIG. 3) and FIG. 6B (magnified), the display panel 2 is now taken out of the holder 44 and mounted to the bag 1 in vertical operating position with the matching parts 41 and 42 of the vertical operating position support fixture engaged and holding the display panel in a position with the display visible from the back to front direction. The vertical support fixture may be arranged to support the display panel at some angle other than parallel to the plane of the bag front but still viewable from a back to front angle extending over the bag top or top wall. Also shown in these drawings are the holder top edge 129, holder front 130 and protective spacers 43.

Shown in FIG. 7A (shown at cross section a-b in FIG. 3) and FIG. 7B (magnified) the display panel 2 is again out of the holder 44 and in another operating position approximately perpendicular to the bag 1 front wall 3 for viewing by an operator from above in the downward direction. Here the matching parts, 41 and 42, are again shown. Also shown is how a display panel retainer such as an attachment flap 128 or filament, which holds the display panel to the bag by attaching to the bag or an interior surface 136 of the holder by its proximal end 128b, extending over the holder top edge and attaching to the display panel proximal edge with its distal end 128a. The section of attachment flap between the holder top edge and the display panel forms a free section 51 of the attachment flap, or filament, which suspends the display panel while a prop/extension 27 of the display panel presses against the holder front, or contact surface 119 if present, to hold the display panel in an operating position, in this case with the display panel plane approximately perpendicular to the holder front and bag front wall. FIG. 7a also shows that electrical equipment 125, such as a computing unit, batteries or communication equipment, may be found in the holder 44 instead of or in addition to electrical equipment found in the display panel or in a separate computing unit panel. The display panel retainer 128 may also serve as an electrical connection to electrically connect the display panel to electrical equipment in the holder.

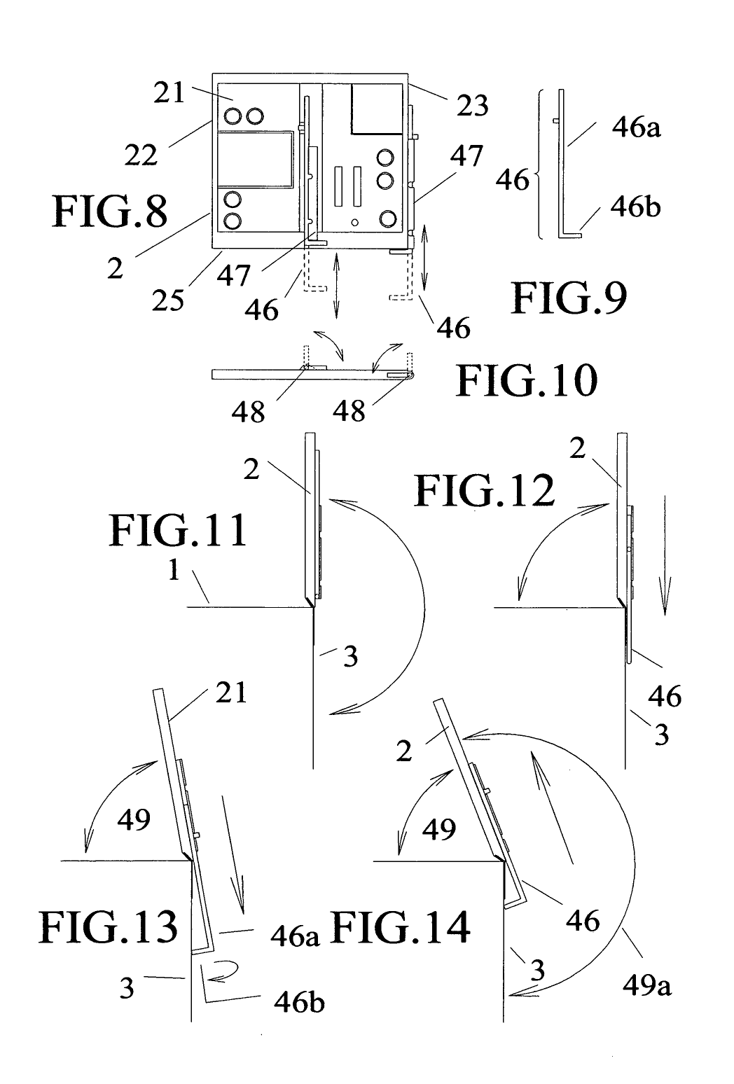

In a different arrangement to improve the display panel, shown in FIGS. 8, 9, 10, 11, 12, 13 and 14, the vertical operating position support fixture is a prop bar 46 attached to the display panel 2 with a vertical operating position support fixture sliding prop holder 47. The prop holder may hold the bar so that it may slide parallel to the plane of the display panel and perpendicular to the attachment edge 25. When the display panel is in the vertical operating position, the vertical operating position support fixture bar may move in the downward and upward directions. In this way, the bar may extend beyond the attachment edge of the display panel and adjacent to the bag front 3 and bracing against the bag front and holding the display panel in a vertical position. If the display panel is designed to mount on a holder, the vertical support fixture bar would brace against the holder front. The vertical support fixture may be mounted on the display panel back side 21 or on a right 22 or left edge 23.

As shown in attachment edge view FIG. 10, the prop bar may be pivot on the display panel. In this case the axis 48 of pivoting is parallel to plane of the display panel and perpendicular to the attachment edge of the display panel.

Further, the prop may be arranged to both slide, as described above, and pivot. A sliding bar prop 46 for such use is shown in FIG. 9 and is comprised of a sliding axis part 46a and a pivoting arm part 46b.

In the vertical operating position the operator may desire to have the viewing angle of the display panel relative to the outside of the bag front wall greater than degrees (for example FIGS. 13 and 14) as in the case where the bag's bottom is against the chest, stomach or lap of the operator. Various arrangements of vertical operating position support fixtures and vertical operating position props, as described below, are arranged to allow the operator to set the display panel at a viewing angle greater than 180 degrees relative to the bag front wall 49a. For convenience, this angular arrangement is shown in many drawings as and is equivalent to a viewing angle 49 of less than 90 degrees relative to the bag top wall.

FIGS. 11, 12, 13 and 14 show a side view of the prop bar mounted to a section of the bag 1 (shown here as only a part of the bag front and top walls) and demonstrate the operation of the vertical operating position support fixture prop bar 46. In FIG. 11, the prop is not deployed and the display panel can move normally. In FIG. 12, the bar has been slid in a downward direction stopping the display panel from being pivoted in a direction toward storage. In FIG. 13, the bar has been pivoted on the display panel so that the pivoting arm part 46b is between the sliding axis part 46a and the bag and projecting in a direction away from the front side of the display panel and toward the bag front while abutting and pressing against it. The sliding axis and sliding arm are located to create a viewing angle 49 between the display panel and the bag front 3. FIG. 14 shows that the viewing angle 49 can be adjusted by sliding the sliding axis part 46 in an upward or downward direction.

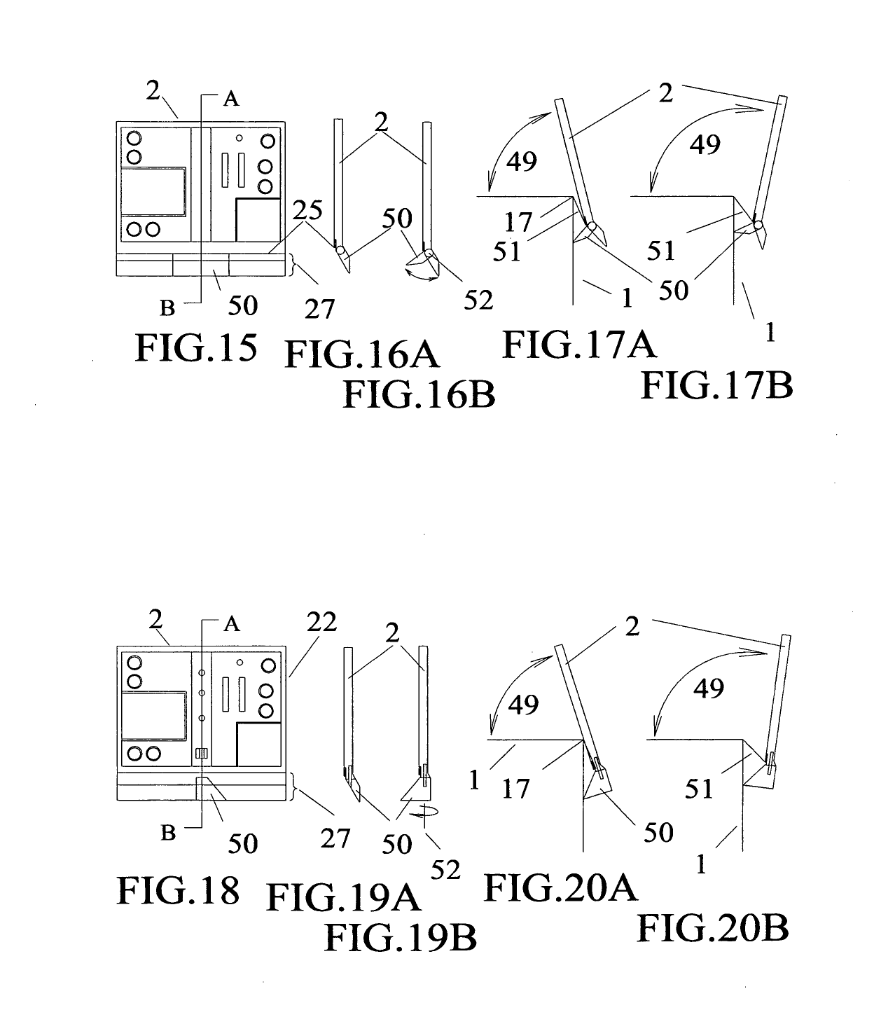

FIG. 15 shows a different arrangement for a vertical operating position prop 50. This arrangement may be used where the display panel includes a display panel extension or leg type prop 27 fixed to the display panel 2 and/or when the mount to a bag includes a pivoting computer equipment mount including a free section. The free section (shown in FIG. 17B, 51) is a part of a pivoting computer equipment mount and is slack or an extra length of material in the mount between the bag and display panel. The free section is used in cooperation with a prop attached to the display panel near the attachment edge to prop the display panel in a variety of angles.

The vertical operating position prop 50, in the case shown, is pivotally mounted to the display panel on an axis parallel to the plane of the display panel and parallel to the attachment edge 25 of the display panel. As shown, if a display panel extension prop 27 is used, the vertical operating position prop may be embedded in, shaped to fit or aligned with a fixed extension prop or a prop leg. Alternatively, the vertical operating position prop may be comprised of the entire display panel extension type prop or a prop leg with the entire structure pivoting.

FIGS. 16A and 16B show a cross section (A/B on FIG. 15) side view of the display panel 2 with the vertical operating position prop 50 pivoted from a stored position FIG. 16A to a deployed position FIG. 16B. The pivoting axis 52 is parallel to the plane of the display panel and parallel to the attachment edge of the display panel is shown.

FIGS. 17A and 17B show a cross section (A/B on FIG. 15) side view of the display panel 2 now mounted to a bag 1 near the junction of the top and front walls 17 (partial view of the bag only) and with the vertical operating position prop 50 in a deployed position. The prop abuts the bag and the free section 51 of the pivoting computer equipment mounts suspends the display panel. The vertical operating position prop 50 is located on the extension prop 27 to extend between the display panel and the bag front and extends away from the display panel front. As shown in 17A, the prop is capable of holding the display panel in a vertical operating position. The angle 49 of the display panel can be adjusted by shifting the position where the prop abuts the exterior of the bag front wall.

Shown in FIGS. 18, 19A, 19B, 20A, and 20B, the vertical operating position prop 50 pivots, in the case shown, on an axis 52 parallel to the display panel plane and parallel to a side edge 22. The prop may be embedded in, shaped to fit or aligned with an extension prop 27 which may be fixed to the display panel and may be immovable relative to the display panel.

FIG. 18 shows a front view with the vertical operating position prop 50 shaped to fit into the display panel 2 extension prop 27.

FIGS. 19A and 19B show a cross section (A/B on FIG. 18) side view of the display panel 2 with the vertical operating position prop 50 pivoted on the axis 52 parallel to a side edge 22 from a stored position FIG. 19A to a deployed position FIG. 19B.

FIGS. 20A and 20B show a cross section (A/B on FIG. 18) side view of the display panel 2 now mounted to a bag 1 near the junction of the top and front walls 17 and with the vertical operating position prop 50 in a deployed position. The angle 49 of the display panel can be adjusted by shifting the position of contact between the prop and the bag. These drawings show the display panel suspended from the bag by a free section 51 of the pivoting computer equipment mount.

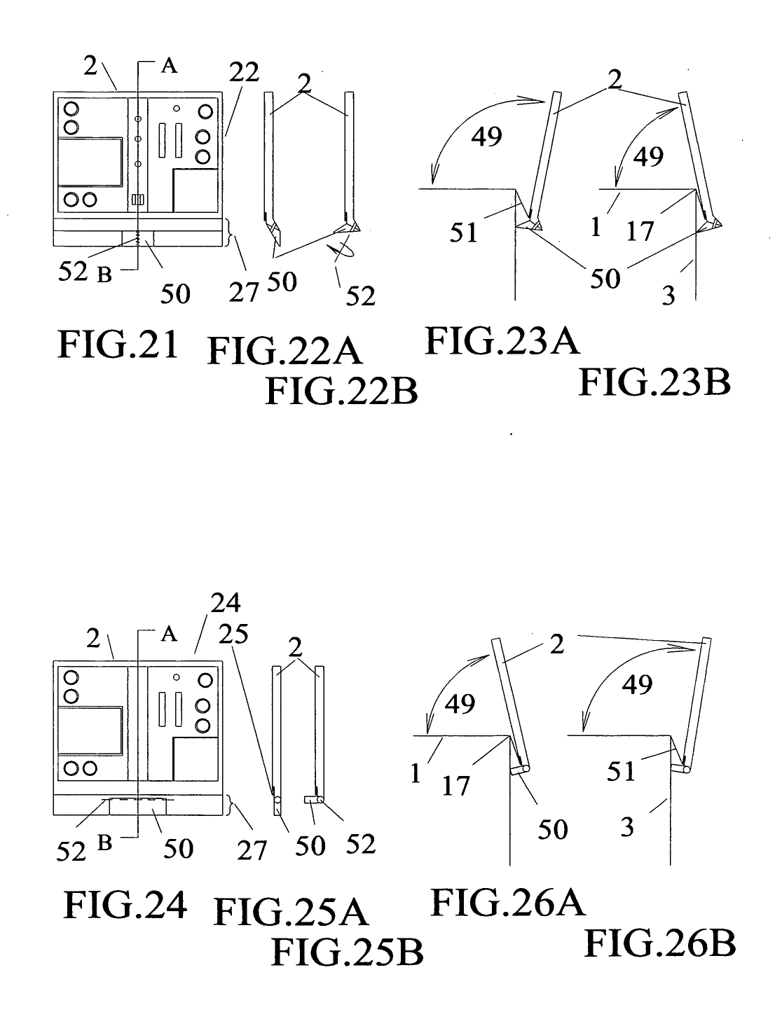

Shown in FIGS. 21, 22A, 22B, 23A, and 23B, the vertical operating position prop 50 pivots on an axis 52 (dashed line) parallel to a side edge 22 but tilted at an angle relative to the display panel 2 plane. The prop may be embedded in, shaped to fit or aligned with a fixed prop extension 27.

FIG. 21 shows a front view with the vertical operating position prop 50 shaped to fit into the display panel 2 extension prop 27.

FIGS. 22A and 22B show a cross section (A/B on FIG. 21) side view of the display panel 2 with the vertical operating position prop 50 pivoted on the axis 52 from a stored position FIG. 22A to a deployed position FIG. 22B. It can be seen that the axis 52 is parallel to a side edge but tilted at an angle relative to the display panel 2 plane.

FIGS. 23A and 23B show a cross section (A/B on FIG. 21) side view of the display panel 2 now mounted to a bag 1 near the junction 17 of the top and front walls 3 and with the vertical operating position prop 50 in a deployed position. The angle 49 of the display panel relative to the bag can be adjusted by shifting the position of the prop on the bag. These drawings show the display panel suspended by a free section 51 of the pivoting computer equipment mount. This arrangement, or any of the other vertical operating position props shown in FIGS. 15 to 37, may be used with a bag front mounted holder (44 in FIGS. 4B and 7A) substituting for the bag illustrated in this drawing.

Shown in FIGS. 24, 25A, 25B, 26A, and 26B, show that the vertical operating position prop may be used when the prop extension 27 is not angled relative to the display panel plane. Here, the vertical operating position prop 50 pivots on an axis 52 parallel to the plane of the display panel and parallel to the attachment edge 25 and distal edge 24 but tilted at an angle relative to the display panel 2 plane. The prop may be embedded in, shaped to fit or aligned with a fixed prop extension 27.

FIG. 24 shows a front view with the vertical operating position prop 50 is shaped to fit into the display panel 2 extension prop 27.

FIGS. 25A and 25B show a cross section (A/B on FIG. 24) side view of the display panel 2 with the vertical operating position prop 50 pivoted on the axis 52 from a stored position FIG. 25A to a deployed position FIG. 25B.

FIGS. 26A and 26B show a cross section (A/B on FIG. 24) side view of the display panel 2 now mounted to a bag 1 near the junction 17 of the top and front walls 3 and with the vertical operating position prop 50 in a deployed position. The angle 49 of the display panel can be adjusted by shifting the position of the prop on the bag. These drawings show the display panel suspended by a free section 51 of the pivoting computer equipment mount.

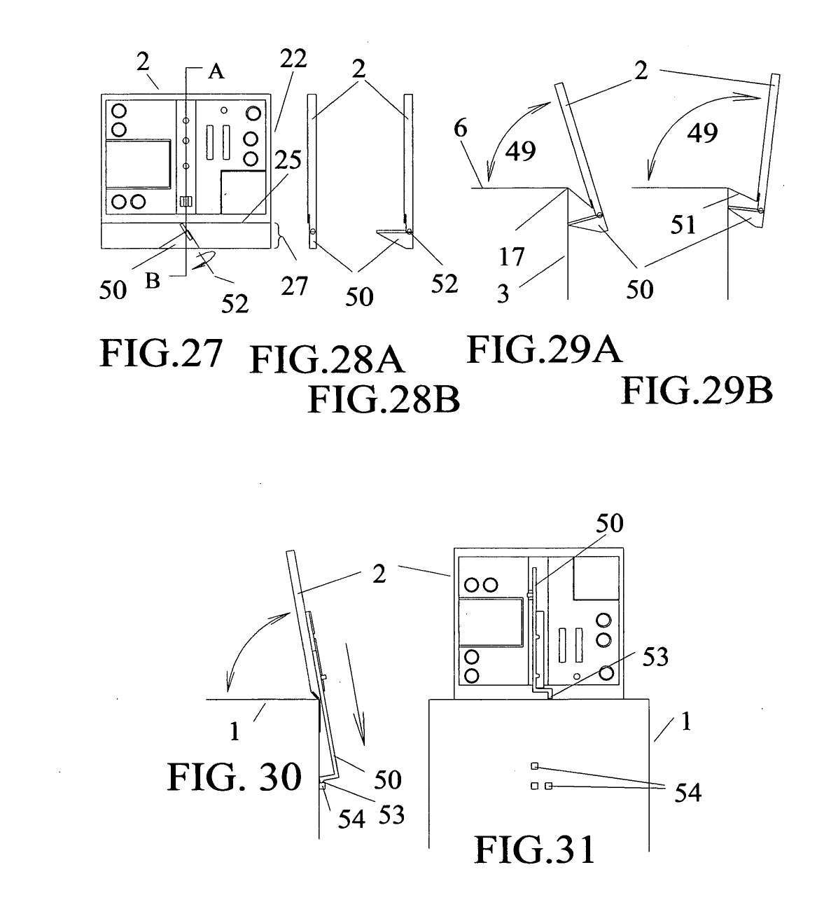

Shown in FIGS. 27, 28A, 28B, 29A, and 29B, show that the vertical operating position prop may be used when the prop extension 27 is not angled relative to the display panel plane. Here, the vertical operating position prop 50 pivots on an axis 52 parallel to the plane of the display panel 2 but tilted at an angle relative to the attachment edge 25 or the a side edge 22. The prop may be embedded in, shaped to fit or aligned with a prop extension which is fixed to the display panel and immovable relative to the display panel.

FIG. 27 shows a front view with the vertical operating position prop 50 is shaped to fit into the display panel 2 extension prop 27.

FIGS. 28A and 28B show a cross section (A/B on FIG. 27) side view of the display panel 2 with the vertical operating position prop 50 pivoted on the axis 52 from a stored position FIG. 28A to a deployed position FIG. 28B.

FIGS. 29A and 29B show a cross section (A/B on FIG. 27) side view of the display panel 2 now mounted to a bag near the junction 17 of the top 6 and front walls 3 and with the vertical operating position prop 50 in a deployed position. The prop abuts the bag and the free section 51 of the pivoting computer equipment mounts suspends the display panel. The vertical operating position prop 50 is located on the extension prop 27 to extend between the display panel and the bag front and extends away from the display panel front. As shown in 29A, the prop is capable of holding the display panel in a vertical operating position. The angle 49 of the display panel relative to the bag can be adjusted by shifting the position of contact of the vertical operating position prop on the bag front wall. These drawings show the display panel suspended by a free section 51 of the pivoting computer equipment mount.

Shown in FIG. 30 (side view) and FIG. 31 (front view), any of the props described herein may include an attachment fixture to temporarily hold the vertical operating position prop 50 to the bag 1. The attachment fixture may include prop part 53 and a bag part 54 that match one another. The prop part of the attachment may be on any part of the prop including the prop sliding axis part or pivoting arm part and may be constructed of flexible fabric, axle and bearing, or other hinge means. There may be more than one bag part or prop part attachment fixture to accommodate various display panel 2 angles.

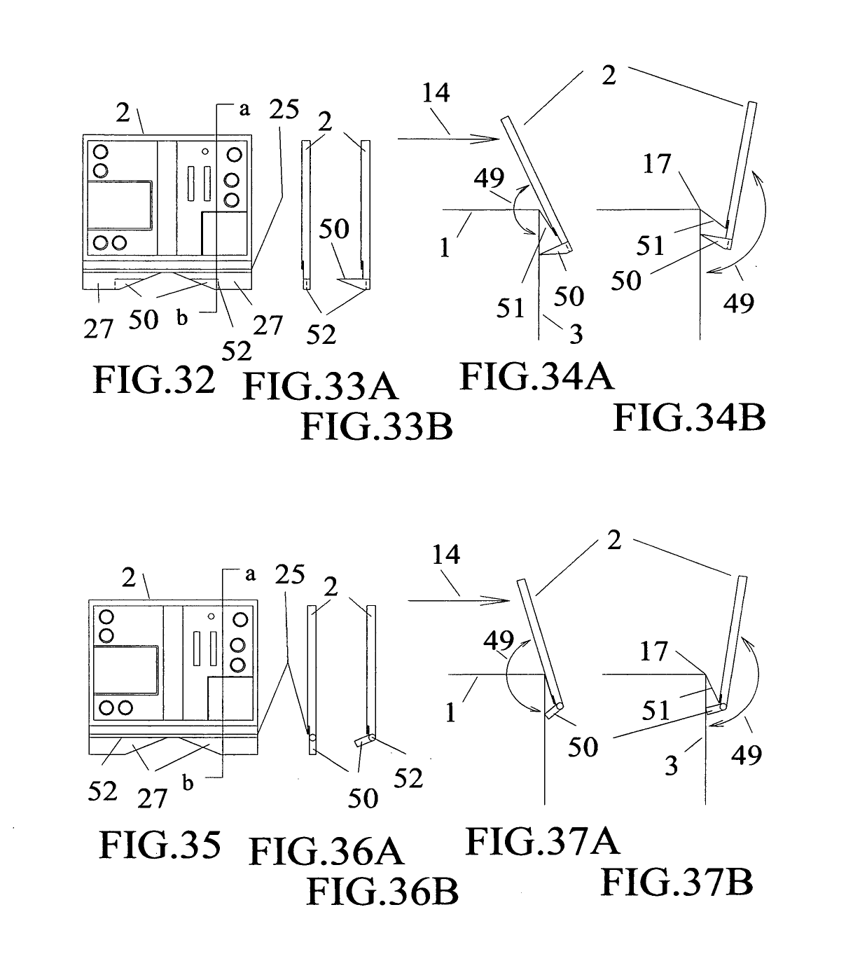

FIG. 32 shows a front view of the bag computer with the vertical operating position prop 50 shaped to fit into the display panel extension prop 27 which extends from the attachment edge 25 of the display panel 2 and may be fixed to the display panel and immovable relative to the display panel. This drawing shows that there may be more than one display panel extension prop and more than one vertical operating position prop.

FIGS. 33A and 33B show a cross section (A/B on FIG. 32) side view of the display panel 2 with the vertical operating position prop 50 pivotable on the axis 52 which may be parallel to a display panel side edge from a stored position FIG. 33A to a deployed position FIG. 33B.

FIGS. 34A and 34B show a cross section (A/B on FIG. 32) side view of the display panel 2 now mounted to a bag 1 near the junction 17 of the top and front 3 walls and with the vertical operating position prop 50 in a deployed position. The angle 49 of the plane of the display panel relative to the plane of the front wall can be adjusted by shifting the position of the prop on the bag thus adjusting the view of the display to an observer viewing in a back to front direction 14. These drawings show the display panel suspended by a free section 51 of the pivoting computer equipment mount.

FIG. 35 shows a front view of the display panel 2 where the display panel extension prop 27 also acts as a vertical operating position prop. The display panel extension prop, here shown as two legs, pivots on an axis 52 to serve as vertical operating position props.

FIGS. 36A and 36B show a cross section (A/B on FIG. 35) side view of the display panel 2 with the vertical operating position props 50 pivotable on the axis 52, which may be parallel to the display panel attachment edge 25, from a stored position FIG. 36A to a deployed position FIG. 36B. In this case, the display panel extension props 27 and the vertical operating position props 50 are the same structures.

FIGS. 37A and 37B show a cross section (A/B on FIG. 35) side view of the display panel 2 now mounted to a bag 1 near the junction 17 of the top and front 3 walls and with the vertical operating position prop 50 in a deployed position. The angle 49 of the plane of the display panel relative to the plane of the front wall can be adjusted by shifting the contact position of the prop end on the bag and adjust the view of the display to an observer viewing in a back to front direction 14.

These drawings show the display panel suspended by a free section 51 of the pivoting computer equipment mount.

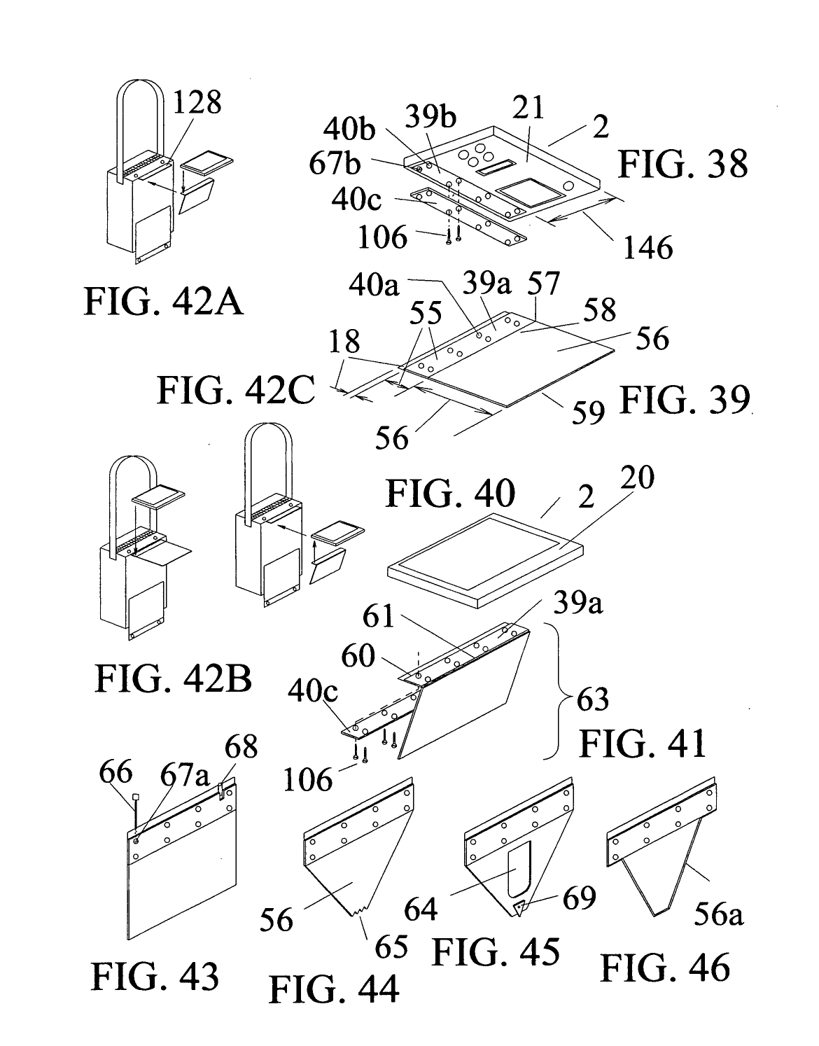

In another different means of holding and propping a display panel on a bag, FIG. 38, FIG. 39, FIG. 40, and FIG. 41 show a folding prop display panel mounting assembly (FIG. 39) and matching display panel (FIG. 38) for this purpose. The bag may be adapted to match the assembly and display panel.

This arrangement allows the display panel to be attached to and propped on the bag while leaving the majority of the back side of the display panel exposed with controls accessible to the operator. FIG. 39 shows the folding prop display panel mounting assembly with parts comprised of an attachment part 55 and a propping part 56. The two parts may be made of light rigid or semi-rigid sheet material or may be frame-like and made of plastic or metal, for example. The two parts are pivotally attached (attachment part distal edge 61 to propping part proximal edge 58) by an attachment part to propping part hinge means 57 which may be constructed of flexible fabric, axle and bearing, or other hinge means.

The propping part is attached to the attachment part by its proximal edge 58 and the propping part has a distal edge 59 which may be adapted to match the bag or a surface or a matching fitting located there so as to temporarily hold the prop in place and prop the display panel at an angle.

The attachment part has a proximal and a distal edge (60 and 61, respectively in FIG. 41), the distal edge being pivotally attached to the proximal edge of the propping part. The attachment part may include an attachment area 39a with an attachment means 40a such as snaps, clamp, adhesive, screws, rivets, hooks, hook and loop, clips or other means to attach the attachment part to a display panel. Attachment may alternatively be by using a clamp or two jaws with, for example, one removable jaw being shown as 40c with fasteners 106 through the mounting assembly attachment part 55 to clamp this jaw to the display panel attachment area 39b (the second jaw) (FIG. 38 and FIG. 41). The display panel attachment area may be located on the display panel back side, may be adjacent to the attachment edge and may cover only a portion of the display panel back side.

To attach the folding prop display panel mounting assembly to the display panel, there may be a matching display panel 2, here showing its back side 21, which has display panel attachment area 39b complimentary to the mounting assembly attachment part attachment area 39a an may include matching attachment means 40b, shown in FIG. 38, a view of the back side of the display panel. The back side of the display panel may include a distal portion 146 of its surface large enough to position controls for use with the operators fingers. The two jaws 39b and 40c may serve as clamping jaws to attach the combined display panel and folding prop display panel mounting assembly to the bag by clamping to a short flexible fabric attachment flap 128 on the bag (FIG. 42A). The folding prop display panel mounting assembly may include an electrical connection to the display panel and/or bag interior such as a specially adapted attachment 67b to electrically connect to a matching electrical connection on the attachment part and from there to electrical and/or computer equipment in the display panel or inside the bag.

FIGS. 40 and 41 show the display panel 2, front side 20 showing, and the folding prop display panel mounting assembly 63 ready to be attached together, here shown situated to hold the display panel in an operating position approximately perpendicular to a bag or other surface it is attached to.

In addition there may be a pivoting computer equipment mount 18 adjacent to the attachment part proximal edge 60 which pivotally and removably attaches the proximal edge of the attachment part to a bag or other surface. It may be constructed of flexible fabric, axle and bearing, clamp, or other hinge means and may be arranged to removable attach the attachment part to the bag or surface. The folding prop display panel mounting assembly may be removable attached to a bag using a pivoting computer equipment mount with the display panel attached to the assembly (FIG. 42A). Alternatively, the folding prop display panel mounting assembly may be permanently and pivotally attached to and be part of the bag (FIG. 42B) and the display panel attaches to the assembly. The mounting assembly may be attached near the top, center or other locations on the bag front wall outside surface. In another alternative, the pivoting computer equipment mount for connection to the bag may be on the display panel and the folding prop display panel mounting assembly mounts directly and only to the display panel (FIG. 42C).

FIG. 43 shows the folding prop display panel mounting assembly in a storage position and shows that an electrical connection 66 may be provided to electrically connect the assembly to the bag interior or display panel. The electrical connection may be an attachment means with special adaptation 67a which can allow an electrical connection between electrical equipment, such as a computing unit, in the bag to the display panel. Alternatively, the assembly may provided with an electrical access opening or channel 68 allowing an electrical connection, such as a wire lead, to pass from the display panel to other electrical equipment held, for example, in the interior of the bag. If the assembly is permanently attached to the bag (FIG. 42B), the electrical access opening may continue through the bag to the interior of the bag. If the assembly is connected to the bag with a clamp, the clamp jaws may be adapted to allow this connection without damaging the connection.

FIG. 44 shows that the propping part 56 may be shaped to suit the particular need. The distal edge of the propping part may be shaped or cut 65 to improve adhesion to the bag when propping. FIG. 45 shows that there may be a shaping feature 64 such as a cut out or other feature cut from or added to the prop. This may aid, for example, in storing the prop against the bag without bag prop fixtures interfering. The distal edge of the propping part may include an adhesion improvement fixture such as a rubber cover or spike 69 to improve adhesion to the bag when propping. FIG. 46 shows that the propping part may be made of some other non-sheet-like material such as, for example, bent wire 56a or a molded plastic frame.

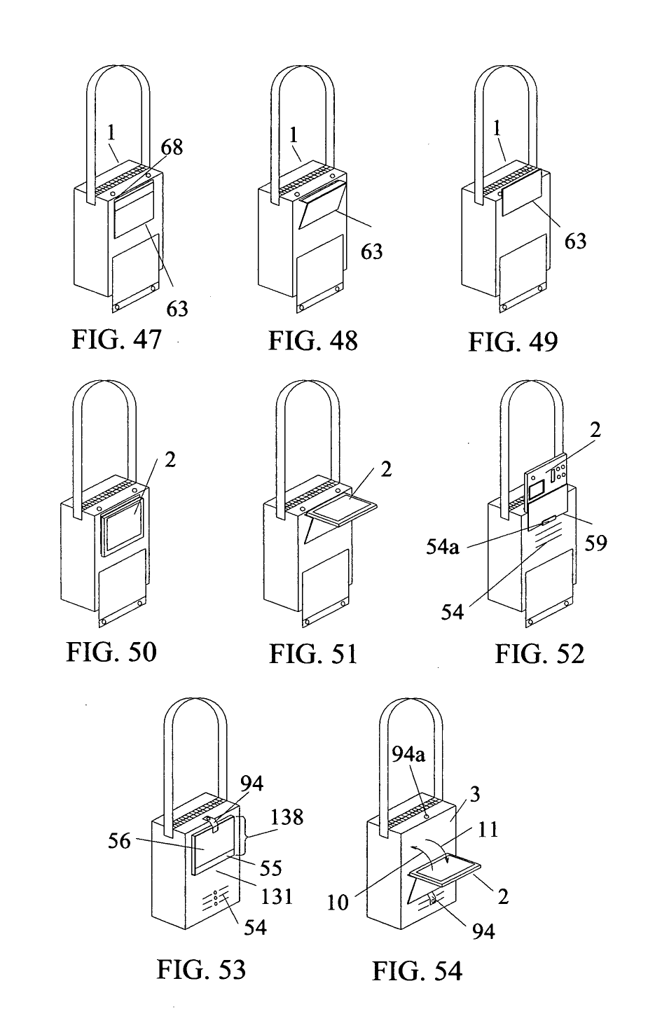

FIGS. 47, 48, and 49 show the folding prop display panel mounting assembly 63 mounted to a bag 1 (without the display panel attached) in, respectively, storage position, an operating position perpendicular to a bag front wall and in a vertical operating position. FIG. 47 shows that the bag may have an electrical access opening 68 to allow an electrical connection between the display panel and electrical equipment inside the bag. FIGS. 50, 51 and 52 show the same order of positions but with the display panel 2 now attached to the folding prop display panel mounting assembly. FIG. 52 shows that the propping arrangement may include one or more bag part attachment fixtures 54 on the bag surface to compliment the distal edge 59 area of the propping part and hold it to the bag surface. The bag to prop part attachment for vertical position 54a, which may be a pocket or hook matching the prop, notch and nubbin/knob/button, matching adhering material or shapes, socket and plug, for example, may be different from the attachment fixtures for other operating positions. The attachments may be of a soft or flexible material and/or be configured to collapse or may be of position and size to fit in a cut out in the propping part to facilitate storing under the prop while in storage position.

FIG. 53 (stored position) and FIG. 54 (operating position) show that this same folding prop display panel mounting assembly may be mounted elsewhere on the outside of the bag front wall 3, for example, near the center 131 (about half way between the top and bottom) or at the bottom of the computer equipment storage area. The display panel may pivot open to an operating position with a downward motion 11 and pivot closed to a storage position with an upward motion 10. The propping part works as previously described to hold the display panel in an operating position. The attachment part 55 and a propping part 56 then form a cover 138 for the display panel when in a stored position. The assembly may then include a closure 94, such as a latch, seal flap or tab, to hold the stored display panel in place. A matching part 94a to the closure may be located on the bag. One or more bag part attachment fixtures 54 may be included on the bag front to match the propping part and temporarily hold it to the bag. The closure may be arranged to match the bag part attachment fixtures and hold the display panel in an operating position.

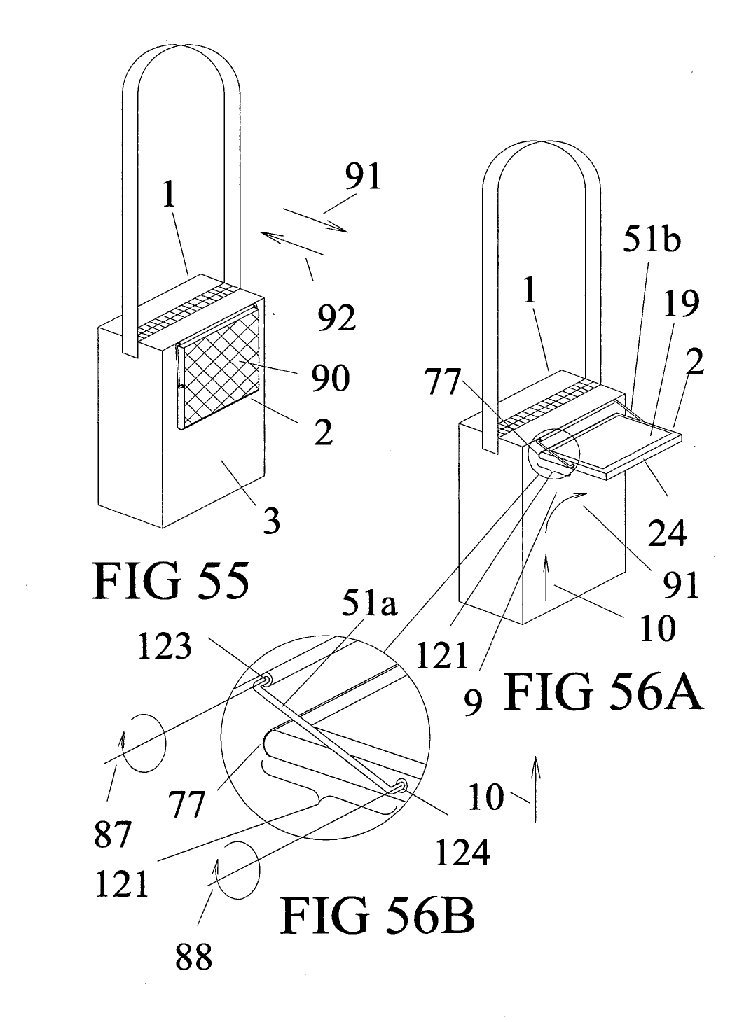

In an alternative way to improve the attachment and propping of a display panel to a bag front, shown in FIGS. 55, 56A and 56B, the display panel 2 may be mounted to a bag 1 front wall 3 using a free section, in this case comprised of a right part 51a free section and left part 51b free section, which suspend the display panel from the bag by the panel right and left side edges and creating a proximal portion 121 (indicated by bracket) of the display panel between the attachment edge and the second pivoting attachment 124 on the display panel. The free sections are attached to the bag at first pivoting attachments 123. The display panel proximal end/edge 77 is pressed against the bag front wall while the free sections suspend the display panel at one or more angles relative to the bag front wall. In FIG. 55 the display panel is in a storage position approximately parallel to the bag front wall in the computer equipment storage area 9. In the storage position, the display 19 on the display panel is facing toward 92 the bag front wall. With the free sections mounted approximately half way between the proximal end/edge 77 and the distal edge 24, the display panel may be stored, in the general case, with the display facing either toward 92 the bag front wall outside surface or facing away from 91 the bag front wall outside surface. In a more specific case shown, the display may be facing the bag front wall while in storage position so as to protect the display without the use of a separate cover. The display panel pivots on a first axis (or hinge) 87 where the free sections attach to the bag. It may also pivot on the second axis (or hinge) 88 where the free section attaches to the display panel. Hinges, flexible fabric or other hinge means may be used for pivoting. If the display faces toward the bag front wall, the back side of the display panel may include a protective surface 90 or cover to protect the display panel.

In FIG. 56A and, magnified, FIG. 56B, the display panel is deployed. In this case the display panel is deployed for viewing into an operating position with a movement upward 10 and display panel pivoting with the distal edge of the display panel moving away from 91 the bag front wall.

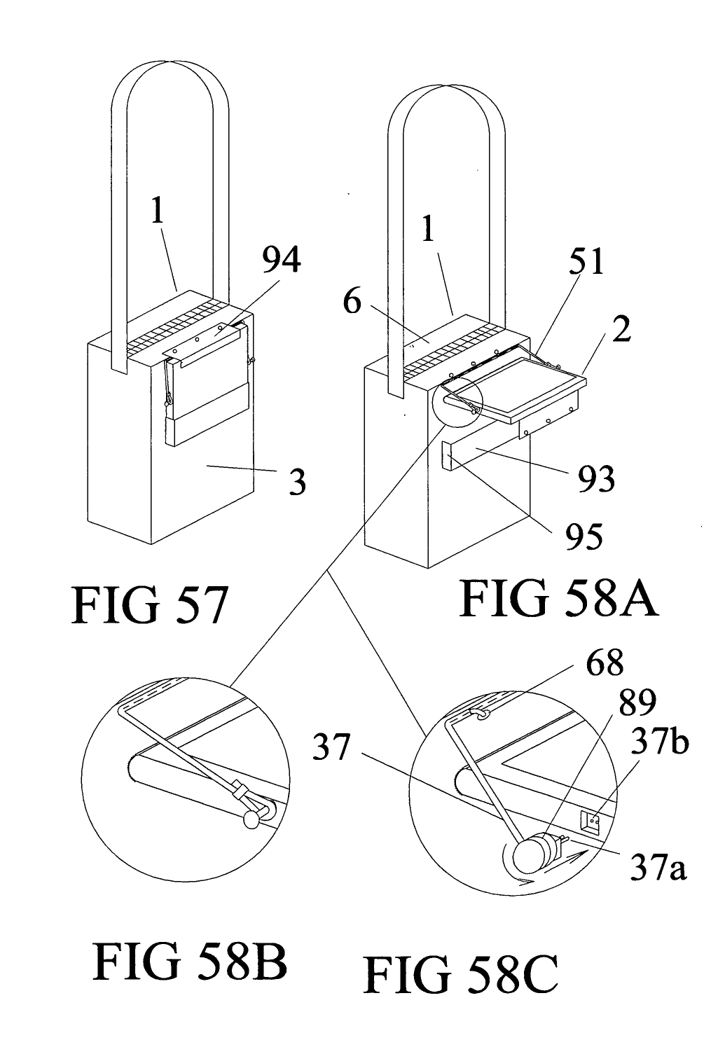

In FIGS. 57, 58A, 58B and 58C, it is shown that the free sections 51 may be of a flexible material such as strands, fabric, filament, cloth, rope, electrical wire, or other flexible material. FIG. 58C shows that the free sections may include or be made of an electrical connection 37 such as a wire. The wire may be removably attached to the display panel with a plug 37a and socket 37b or other electrical connection means. The connection may swivel 89 to match the movement of the display panel. The wire may lead to the interior of the bag through an electrical access opening 68 in the bag front wall to connect with other electrical equipment such as a computing unit, batteries or other equipment. The bag 1 front wall 3, top wall 6 or display panel 2 may include a display panel holder assembly including such components as a footing 93, header such as a seal flap closure 94 and/or side guides 95 to help hold the display panel to the bag in storage position against the bag front wall. The header may at least in part be located on the display panel using, for example, a tab or flap and fastener, hook and loop or other closure means.

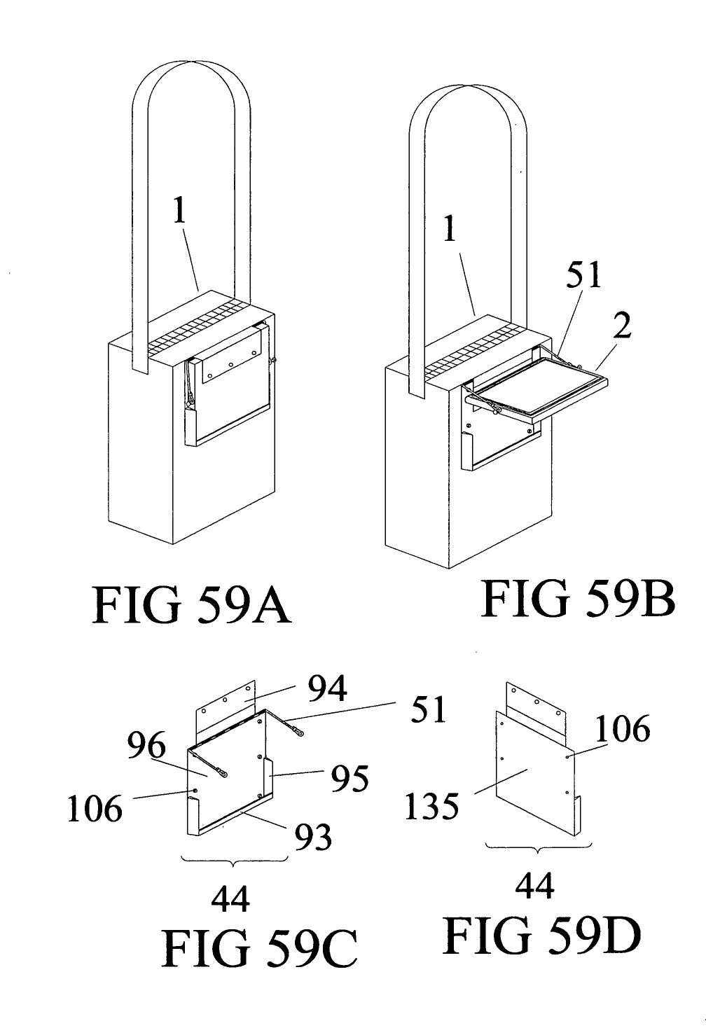

Shown in FIG. 59A (storage position), FIG. 59B (an operating position) the bag 1 may include free sections 51 mounted to it and designed to hold the display panel 2. The bag may include a header, footing and/or side guides are described below.

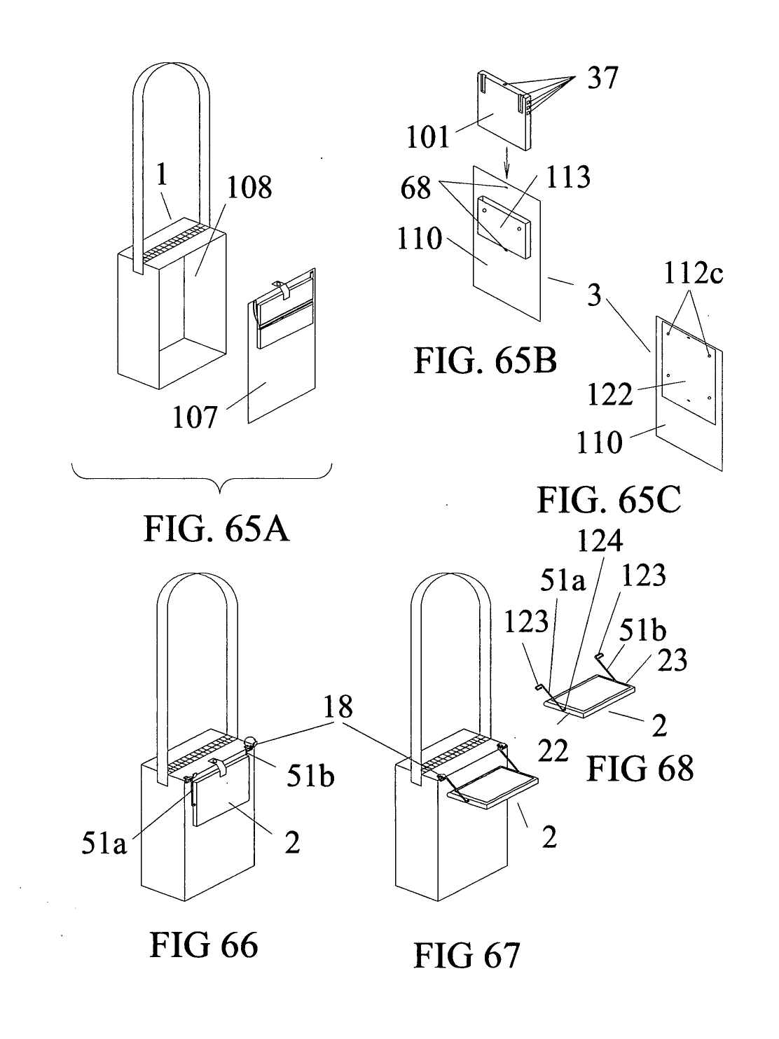

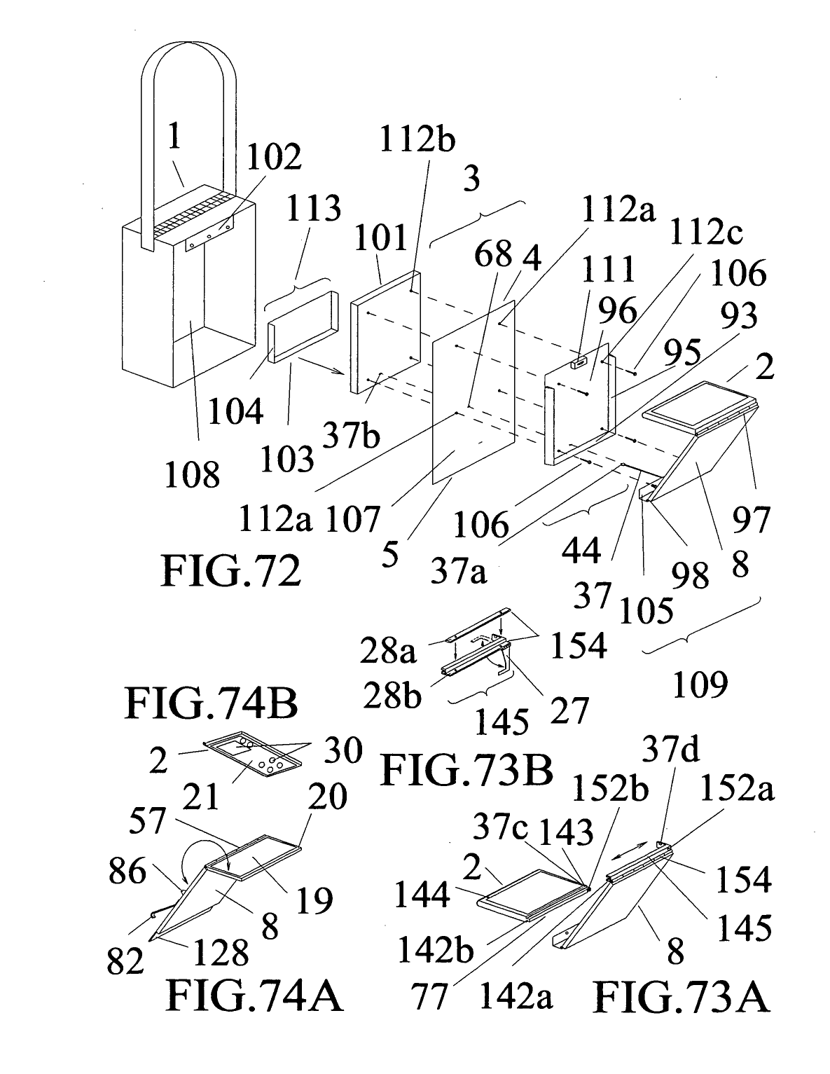

Shown in FIG. 59C, a protective plate 96 may be included to fit the bag and to protect the display from damage caused from the inside of the bag. The protective plate may be joined to the footing 93, header 94 and or side guides 95 to form a single display panel holder 44, shown as a separate unit separated from the display panel and bag in FIG. 59C, which may be sized and shaped to fit the display panel 2. The protective plate or holder may have attachment means 106 matching attachments and/or pattern of holes in the bag (see FIGS. 72, 106, 3, 112a and 112b) and/or a computing unit panel (see FIG. 72, 101), including a computing unit, on the inside of the bag front wall and attach the holder to the bag. The free sections 51 may be attached to the bag or may be, as in the pictured case, attached to the display panel holder with the display panel being removable from the holder and free sections. The free sections may be in the form of a loop (see FIG. 61). FIG. 59D shows the holder protective plate may have a back side 135 with attachment 106 to match a surface, such as a bag front, or through a surface to a computing unit or backing plate (see FIGS. 65C and 72).

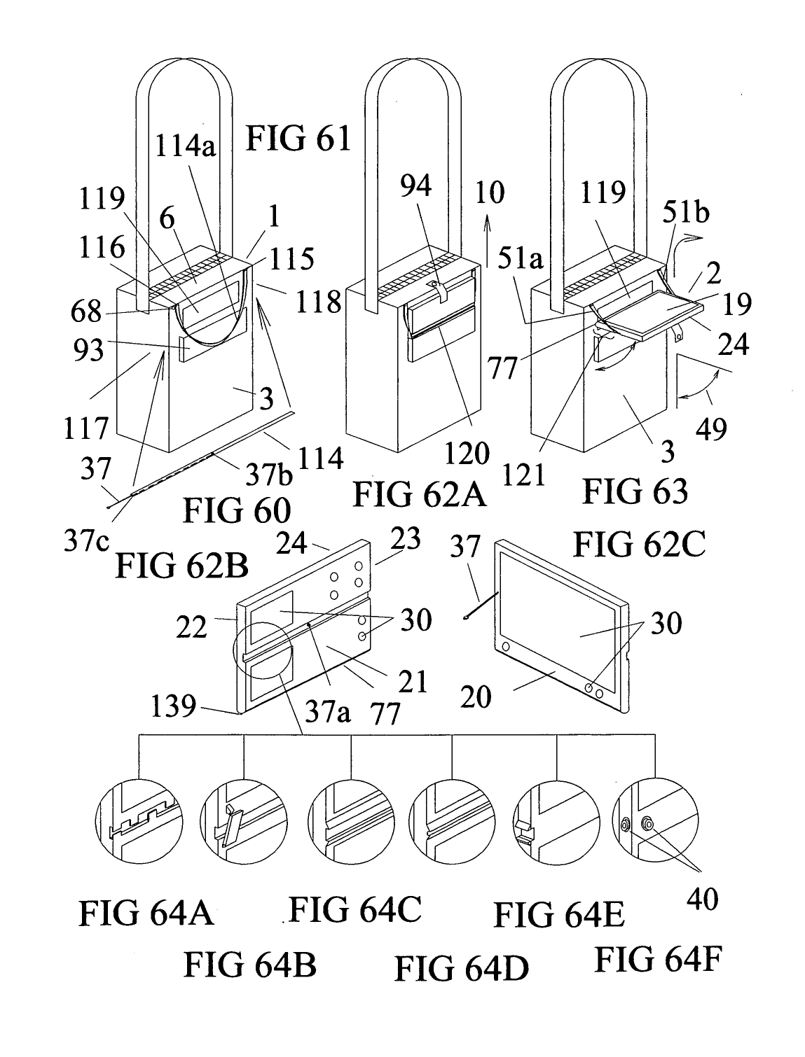

FIG. 60 shows a mounting strap 114 to be attached to a bag to support a pivoting display panel on the bag front wall. The strap may include or be an electrical connection 37 and have a disconnection feature such as a plug or socket 37b. The connection may pass to the interior of the bag through an electrical access opening 68.

In FIG. 61 the strap is attached to the bag 1 by its two ends forming a loop 114a that allows it to support a display panel at a variety of angles. The strap be made of a strip of flexible fabric, belting (which may be double layered or tubular 37c to accommodate an electrical connection wire), electrical wire, elastic, filament, rope, or other linear flexible material and may be attached to the bag using sewing, riveting or other attachment means. The loop may alternatively be made of rigid material such as wire or plastic. The strap has a first strap end 115 attached to the bag toward the bag top 6 and toward the bag right side 117 and a second strap end 116 attached toward the bag top and toward the bag left side 118. The ends may be attached to the bag at angles or with swivels to facilitate the movement of the display panel into and out of storage.

The bag may include a support structure such as a holder to hold the display panel against the bag front wall 3 when it is in a storage position. The holder may be made of or include a footing 93, such as a pocket, frame, band, or other feature to hold the display panel area near the proximal edge area to the bag while in storage. The holder may be made of or include a head piece, such as a seal band or flap with attachment, to hold the display panel area near the distal edge to the bag while in storage.

The bag may include a contact surface 119 which is adapted to temporarily adhere the proximal edge of the display panel to the bag front wall. The contact surface may be made of a material that is heavy, roughened, rubberized and/or include features such as ridges, bumps, pits, or other relief that temporarily holds the proximal end of the display panel to the bag. The contact surface may match the proximal end of the display panel with matching sockets and plugs, teeth, ridges or other features. The contact surface may be one or more panels attached to the bag, sewn on fabric or belting, bonded rubberized paint or other means of providing a surface adapted to temporarily adhering to the display panel proximal end.

Shown in FIG. 62A, the display panel is shown mounted to the bag with the strap loop and in a storage position. The display panel is shown held to the bag with the aid of the holder including a head piece 94. In FIG. 62B, the same display panel is shown without the bag. The display panel has a right side edge 22, a left side edge 23, a back side 21, a distal edge 24 and a proximal edge 77. The strap loop removably attaches to and holds the display panel by the display panel back side and/or by the display panel right side edge and left side edge. The back side of the display panel may include a control such as a touch pad or buttons, to control the display or associated computing equipment. The back side may have an electrical connection 37a to electrically attach the display panel via the mounting strap to other electrical equipment which may be found in the interior of the bag. The electrical connection may be combined with an attachment means. FIG. 62C shows the front side 20 of the display panel which may include a display and/or a control 30 such as a button, switch or a touch screen on the display. The display panel may include a computing unit.

The display panel may include an electrical connection 37 connecting the display panel to a computing unit, batteries or other peripherals in the bag interior or attached to the inside or outside surface of the bag front wall.

FIG. 63 shows that the display panel 2 distal edge 24 may be lifted up and away from the bag front wall into a operating position with the display 19 facing upward 10 and viewable by an operator. When the display panel is in storage position (as in FIG. 60A) the display may be facing a front to back direction and toward the bag and its front wall. The strap loop forms a right free section portion 51a and a left free section portion 51b and a back portion 120 along the back of the display panel. The location of contact of the right and left free section portions of the strap an the display panel right and left side edges suspends the display panel while a proximal portion 121 (shown with a brace) of the display panel, including the proximal edge 77, pushes against and temporarily adheres to the bag front wall 3 and contact surface 119, if present, to hold the display panel at one or more angles 49, such as but not limited to 90 degrees, relative to the bag front wall. The proximal edge may include a gripping feature 139 to assist in holding the edge to the bag or contact surface and the gripping feature may match the contact surface. The display panel may have protective spacer rails 43 as shown in FIGS. 2A, 2B, 5 and 4B.

FIGS. 64A, 64B, 64C, 64D, 64E and 64F, all magnifications of the loop connection area on the display panel, show that attachment features of the strap to the display panel may be by its back side and may include, for example, a groove with teeth FIG. 64A or holding feature such as a latch FIG. 64B to hold a strap in place, spaced ridges above the surface of the display panel back side to hold a belt FIG. 64C or wire or rope FIG. 64D. The strap loop may alternatively be held to the display panel side edges with an attachment that is a groove for a belt FIG. 64E on side edges or rope, or with ridges above the surface on the side edge adapted to fit a belt, rope or other type of strap. FIG. 64F shows that the strap may be held to the display panel by one or more attachments 40, such as a snap, hook, hook and loop or other attachment means, on the back side or the side edges of the display panel and matching an attachment on the strap. Side edge attachments may include holding features as with the back side feature in FIG. 64B.

FIG. 65A is an exploded view of the bag 1 showing the interior 108 of the bag and the outside surface 107 of the bag front wall. FIG. 65B and FIG. 65C, two views of the inside surface 110 of the bag front wall 3, the bag may have an inside mounted panel, such as a rigid panel 122 or computing unit panel 101, to make the bag front wall rigid and facilitate the storage of the display panel on the outside surface of the bag front. The rigid panel or computing unit panel may be removably attached to the inside surface of the bag front wall with an inside support structure 113 or with attachment 112c to the bag or through the bag to an outside components and the front wall may include electrical access openings 68 to electrically connect the computing unit panel with the outside mounted display panel. The computing unit panel may include telecommunications, batteries and/or one or more electrical connections 37, such as electrical sockets, to removably connect to the outside display panel, or batteries, memory or other peripherals located in the interior of the bag.

As an alternative way to arrange a display panel 2 with free section mounting to removably attach to a bag, shown in FIG. 66 (storage position), FIG. 67 (operating position) and FIG. 68 (display panel alone), there may be a right free section portion 51a and a left free section portion 51b attached to the display panel right side edge 22, a left side edge 23 with a second pivoting attachment 124 near each side edge. The free sections may be rigid or flexible. Each free section includes a display panel part first pivoting attachment 123 designed to pivotally attach the free section and display panel to the bag. The bag may be designed for the attachment of this display panel by including one or more bag part first pivoting attachments 18, such as one or more attachment straps, matching the display panel part first pivoting attachments to removably hold the free sections and display panel to the bag or to a holder similar to the one shown in FIG. 59C and FIG. 59D.

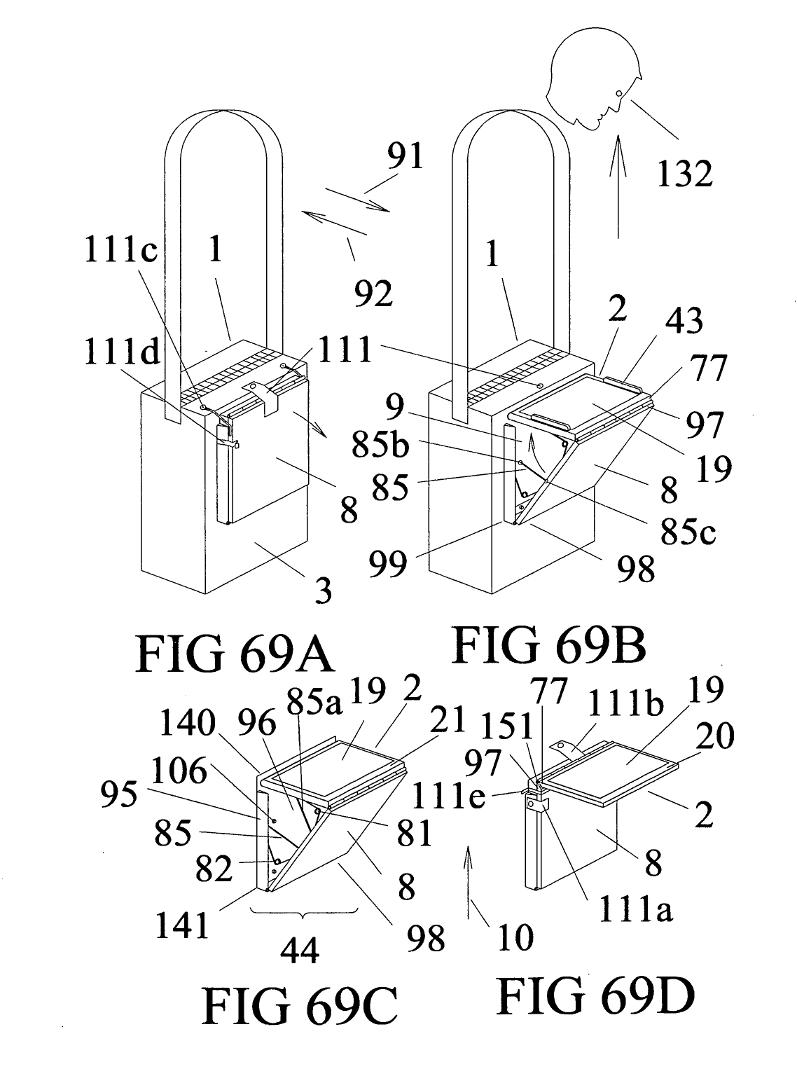

In another different way to mounting and propping of a display panel to a bag front, FIGS. 69A, 69B, 69C and 69D show an embodiment of a display panel mounted to a bag that includes two panels, a display panel 2 and a cover 8, together called a cover/display assembly, mounted to the bag. This two panel folding display panel mounting assembly may include a cover that may be panel-like, rigid and of sufficient strength to support the weight of the display panel while it is in an operating position. The cover serves as and may alternatively be called an intermediate panel between the attachment at the bag and the attachment at the display panel. The cover may be pivotally attached by its proximal attachment edge 98 to the bag front wall 3 outside surface at or near the bottom end 99 of the computer equipment storage area 9 so that it may pivot closed toward 92 the bag front wall outside surface to cover the display panel when it is in storage position or pivot open away 91 from the bag front wall outside surface to open the cover and display panel to expose the display 19 for viewing in an operating position. In this case, the display panel is pivotally attached by the display panel proximal edge 77 to the cover at or near the cover distal edge 97. As the cover opens, the display panel pivots open from a storage position (shown in FIG. 69A) approximately parallel to the bag front wall, between the cover and bag and with the display panel back side facing toward 92 the bag front wall or protective plate, if present, to a first operating position (shown in FIG. 69B) with the display 19 on the back side 21 of the display panel 2 facing upward 10 at the eyes of an operator/bag wearer 132, in this case, with the display panel approximately perpendicular to the bag front wall. The display panel may include protective spacers 43 located on a side or an edge of the display panel to keep the display from rubbing or scratching against the bag or parts or the cover/display assembly. A closure 111, such as a latch, button and hole, hook and loop, tab and snap, hook and bail, spring clip, cover elastic device, retaining band or other closure means, may be located between the cover and bag (or holder if present) to hold the cover and/or display panel in the storage position on the bag. The bag may have a matching part to the closure. The closure may be located near the top end of the computer equipment storage area. The closure may be arranged to hold the cover closed in a storage position while the display panel is still open in a second operating position and may be located on a side of the cover, for example 111a (tab and snap/hook), 111c (loop and button), 111d (spring clip), or 111e (retaining band). A cover closure part 111b may be located on the inside surface of the cover or on the cover to display panel hinge so it may be used to keep closed the cover when the display panel is in a second operating position. The angular movement between the cover and bag front into or out of an operating position may be assisted by a cover elastic device 82, such as a cover spring, spring clip, spring leaf or rubber, which may assist in moving the cover between a storage position and an operating position. The elastic device may serve to keep the cover open and/or to keep the cover closed when, for example, the display panel is in a second operating position. The angular movement between the cover and bag front may be restrained in angular movement by a cover restraining means 85 such as a restraining line, restraining sheet, cover restraint prop or cover angle stop (see 85d, FIG. 71B and 50 FIG. 71C), restraining pocket or other means. The purpose of the cover restraining means is to allow the cover to pivot open from a storage position into an operating position with an angle 134 (see 71C) large enough for the display panel to pivot out of storage and into an operating position while at the same time limiting the movement of the cover and holding the display panel toward the top of the bag and close to the eyes of an operator/bag wearer so the apparent size of the display is still large and viewing is enhanced. The cover restraining means may also be used to position the display farther away from the bag front where it may be easier to view and operate. The cover restraining means may hold or lock the cover in the operating position. The cover restraining means may be a part of the bag/cover combination, a part of the bag and removably attached to the cover with a cover restraint attachment means 85c or may be part of the cover and removably attached to the bag with a bag restraint attachment means 85b. There may be a display panel elastic device 81, such as a display panel spring or rubber, between the cover and display panel to assist in moving the display panel into a viewable operating position relative to the bag front as it is deployed. There may be a display panel restraining means 85a, such as a restraining line or display panel angle stop (see 85a, FIG. 69C and 79, FIG. 71B), between the cover and display panel. As shown in FIG. 69C, there may be a separate and complete holder 44 to hold the cover to the bag front wall (here shown with the cover and display panel attached). The holder may include a protective plate 96, side guides 95, header and/or footing to protect the display panel and/or as a means to attach the holder, cover and display panel to the bag 1. The holder or protective plate may hold electrical equipment such as a computing unit, radio communications, batteries or other equipment. This holder may have means of attachment 106 (see FIGS. 72, 106, 3, 112a and 112b) meant to match and hold the cover and display panel to the bag or computing unit panel (see FIG. 72, 101). The cover may be pivotally attached by its proximal attachment edge 98 to the holder or protective plate instead of to the bag front wall. To deploy, the cover pivots away from 91 the bag front wall, or holder if present, and the display panel pivots upward 10 with the display panel back side 21 with display 19 facing upward into a first operating position. Controls (see FIG. 74B) may be on the side opposite the display (display panel front side). As shown in the drawing, the upward 10 direction is also the direction from the bottom 141 to the top 140 of the holder protective plate. FIG. 69D shows that the cover 8 distal edge 97, display panel 2 proximal edge 77 and display panel to cover hinge 151 may be configured to allow the display panel to pivot further on the cover until the display panel front side 20 is facing upward in a second operating position. For example, an attachment flap and clamp may be used as a hinge. In this case, the display 19 would be located on the display panel front side. In this position, the cover may be pivoted back into the closed (storage) position while the display panel is still open in a second operating position. The closure 111 may be located on the side of the cover to allow this positioning.

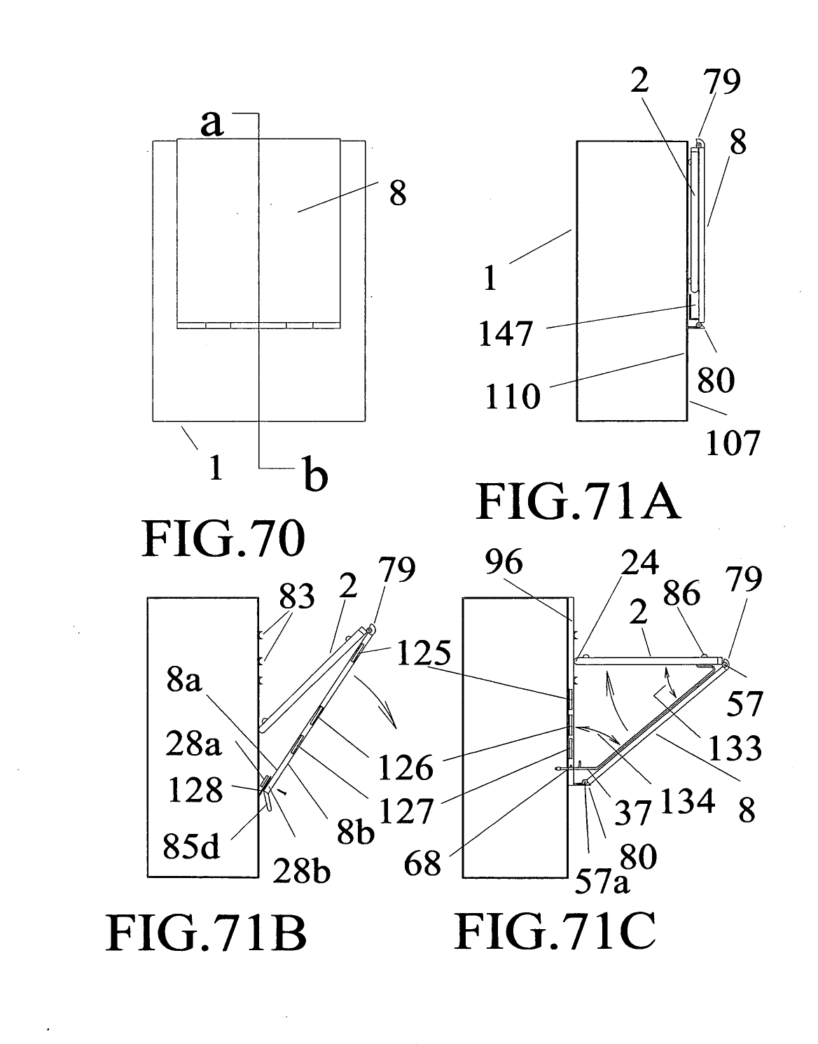

FIGS. 71A, 71B and 71C show more detail of the two panel folding display panel mounting assembly, in particular the operation of the cover 8 mounted display panel 2, shown in side view cross section at a/b in FIG. 70. FIG. 71A shows the display panel and cover in storage position with the display panel between the cover and the bag with the display panel against the bag front wall which may have an outside surface 107 and an inside surface 110. Also shown is a storage chamber 147 attached to the cover or bag and suitable for related electrical equipment such as earphone or microphone. FIG. 71B shows the display panel in the process of being opened and at approximately 30 degrees. The cover, including an inside surface 8a and an outside surface 8b, may be pivotally attached to the bag by its proximal attachment edge. The cover distal edge moves open away from the bag front wall to an operating position. At the same time, the display panel proximal edge is pivotally attached to the cover distal edge and the display panel distal edge 24 moves from a storage position next to the cover inside surface upward to a first operating position (FIG. 71C).

Also shown in FIG. 71B (only) is that the cover may be removable using a pivoting attachment (pivoting computer equipment mount cover part) at the proximal edge of the cover. The attachment may be a clamp, such as two jaws 28a and 28b, clamping onto a short flexible fabric attachment flap 128 (pivoting computer equipment mount bag part) attached to the bag front near the bottom end of the computer equipment storage area. Alternatively, the clamp may be used to attach the cover to an attachment flap on some other object. The display panel may include a cover restraint prop 85d near the cover proximal attachment edge which presses against the bag front when in operating position and holds the angle between the cover and bag front in an operating position. This arrangement may be used with a computing unit panel mounted to the inside surface of the bag front wall thus making the bag front rigid (see 101, FIG. 72). FIG. 71C shows alternative cover to bag pivoting attachments 57a, such as an axle bearing hinge, clamp and attachment flap or other hinge means, may be used. There may be alternative display panel angle stop 79 to limit the angle 133 between the display panel and the cover and a cover angle stop 80 to limit the angle 134 between the bag front wall and the cover. The hinges may include an angle holding mechanism such as a friction or ratchet arrangement. The stop or stops may be contrived to stop/hold the display panel at a variety of operating angles. The bag 1 may have contact points 83 to match and to temporarily attach the display panel distal edge 24 to the bag front wall or holder in one or more display panel angles, as shown in FIG. 71C. The display panel may have bumpers 86 to keep the display from touching the bag front wall or the protective plate of the holder. There may be an electrical connection 37 connecting the display panel to the cover or protective plate 96 electronics, such as computing unit 125, radio communications 126 or batteries 127, storage chamber electronics 37f and/or through an electrical access opening 68 in the bag front wall to other electrical equipment held in the interior of the bag or on the inside surface of the bag front wall (the protective plate is shown only in FIG. 71C). The display panel, cover or protective plate may have their own electrical connections for external devices such as earphone or microphone.

FIG. 72 is an exploded view of the two panel folding display panel mounting assembly including a bag 1 with display panel 2 and other related components. The bag may include an interior 108 and components for an inside support structure 113, which may include a header flap 102, designed to hold a computing unit panel 101 to the bag. The bag may include a front wall 3 which may have top edge 4, a bottom edge 5, an outside surface 107 and an opposite inside surface facing the interior of the bag. Components of the computing unit support structure, such as a footing 103 or side guides 104, may be mounted on the inside surface of the bag front wall. The holder 44 may be shaped to fit the display panel and/or cover. The holder or its components, such as a header (here shown as a latch 111 but may be some other closure such as a seal flap, hook and loop, tab and snap or other means of holding the display panel and/or cover in storage position on the bag), protective plate 96, footing 93 or side guides 95, may be located on and attached to the outside surface of the bag wall. The cover 8, with the display panel pivotally attached at the cover distal edge 97, may be pivotally attached by the cover proximal attachment edge 98 to the holder or protective plate near the footing area 93. Alternatively, the cover/display panel assembly may be separately attached directly to the bag front, holder or protective plate with a separate cover mounting structure 105. Attachment may be done with an attachment means such as rivets, bonding, adhesive, plugs, screws or fasteners 106 passing from (or through holes 112c in) the outside components, such as the protective plate or cover/display assembly 109, through the bag front wall to the inside components, such as the computing unit panel, through a matching pattern of holes 112a in the bag and components to hold the computing unit, bag, holder and cover/display assembly together. Other attachment means 112b may have matching components on an outside component, the bag and an inside component. A computing unit or other electronics may be located in the display panel, in the cover, in the protective plate, the computing unit panel or elsewhere in the interior of the bag. An electrical connection 37, possibly including a disconnectable connector 37a, may be included and may connect electrical equipment in the display panel, cover or holder through an electrical access opening 68 the bag front wall to the computing unit panel using a connecting part 37b on the computing unit panel. The computing unit panel may include electrical connections for electrical equipment such as batteries, memory or peripherals held in the interior of the bag (see FIG. 65b, 101, 37). As shown in FIG. 59D the protective plate of the holder may have a back side 135 which may be adapted for attachment to a surface, such as a bag front, or through a surface to a backing plate or computing unit 101 and may include attachment means 106 for this purpose.

As shown in FIG. 73A the display panel 2 may be removable from the cover 8 so the display panel may be used as a hand held tablet, mobile phone, PDA or smart phone. The display panel may be a display panel and display panel clasp 145 combination pivotally attached to the distal edge of the cover with a display panel clasp to cover attachment 154, such as an axle/bearing hinge or clamp/attachment flap hinge. The display panel clasp is designed to removably hold the display panel and electrically connect it to other electrical equipment. The display panel clasp may have a clasp holding attachment 142a matching a display panel holding attachment 142b for this purpose. The holding attachments may be matching rails with the display panel may slide in from a side as shown, for example, along the display panel proximal edge 77. A locking mechanism with matching display panel part 152b and display panel clasp part 152a may be included to secure the two parts together. The display panel may be of a size and shape to be useful as a telephone handset and may include a speaker 143 and a microphone 144 located on the panel for such use. There may be an electrical connection between a display panel electrical link 37c and a matching holding attachment electrical link 37d on the clasp which may further electrically connect to electrical equipment in the cover, protective plate, holder, computing unit panel or bag interior. The display panel clasp may include a display panel restraining means and/or display panel elastic device between the cover and clasp (shown in 79, FIGS. 71C and 81, 69C). FIG. 73B shows the display panel clasp 145 removed from the cover. The clasp to cover attachment 154 may be a clamp with two jaws 28A and 28B meant to match an attachment flap on the cover distal edge. Also shown is that the clasp may include a display panel prop 27 (the dotted image is the storage position) pivotally attached to the clasp to hold the clasp and display panel in an operating position when a flexible fabric attachment flap is used as a hinge. The clasp may include an electrical connection 37 continuing from the clasp to electrical equipment found in the cover, bag interior, holder, computing unit panel or pocket.

As shown in FIG. 74A, the display panel may be further pivoted on the cover 8 to a second operating position, as shown, so that the display panel front side 20, which may include a display 19, is facing upward toward the operator. The hinge means 57 between the display panel and the cover may be designed to hold any angle using, for example, friction or ratching. Alternatively, the hinge may be a flexible fabric attaching the display panel and cover. As in FIG. 73, the display panel may be physically and electrically removable from the cover for use as a telephone handset, for example. The cover may include a bumper 86 to keep the display from touching the cover. The cover may include a flexible fabric attachment flap 128 on its proximal edge which may be sewn, riveted, clamped or otherwise attached to the bag. Also shown is that the cover elastic device 82 may be a spring leaf. Shown in FIG. 74B, with the display panel 2 inverted in the second operating position, there may now be controls 30 (see FIG. 2C) on the back side 21 of the display panel (facing downward).

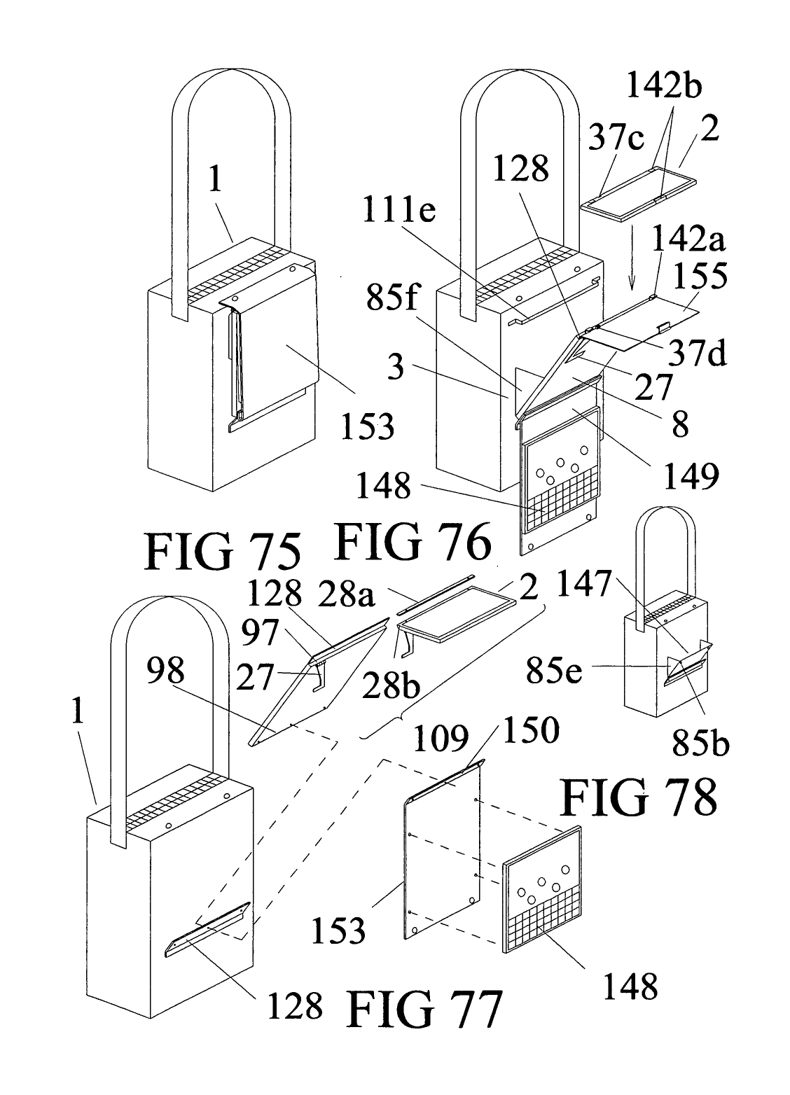

FIG. 75 shows the cover/display assembly in storage position on a bag 1 and covered by a secondary cover 153. In FIG. 76, the display panel is deployed in a second operating position. The cover 8 is held at an angle relative to the bag 1 front wall 3 using a cover restraining means, such as a restraining sheet 85f, and the display panel 2, here with the display on the display panel front side, ready for use. The display panel may be removable and for this objective may include a mounting panel 155 designed to attach the display panel to the cover with the mounting panel against the display panel back side. Matching holding attachments 142a (mounting panel) and 142b (display panel) may be included. A mounting panel electrical connection 37d to connect with a display panel electrical connection 37c may be provided to electrically connect the display panel to the mounting panel, cover, bag interior and/or protective plate (if present). The mounting panel may be removable or may be permanently attached to the cover with a hinge means such as a flexible fabric attachment flap 128. The display angle relative to the cover may be held in and operating position with a display panel prop 27 mounted to either the display panel, the cover, mounting panel or the display panel clasp with, for example, a pivoting hinge which allows it to be stored against the display panel or cover when not in use. A retaining band 111e, which may include elastic, may be included to hold the cover closed in storage position whether or not the display panel is open in a second operating position. The secondary cover 153 inside surface 149 may include an input device such as a keyboard 148 or electronic write pad.

FIG. 77 is an exploded view of the cover/display assembly 109 and bag showing various parts and their assembly. An input device 148 (keyboard) may be removably attached to the inside surface of the secondary cover 153 (4 dotted lines). The secondary cover attachment area 150 may act as a first jaw and the cover/display assembly cover proximal attachment edge 98 may act as a second jaw to clamp and pivotally attach the cover and secondary cover to an attachment flap 128 attached to the bag front (alternatively sewn or riveted). The single dotted line shows an attachment path. A separate removable jaw or jaws may be used instead of or in conjunction with this arrangement.

A clamp and attachment flap 128 may be used to attach the display panel or display panel clasp to the distal end 97 of the cover. An electrical connection 37 may be adapted to pass through the attachment flap and electrically connect the display panel and its clasp or mounting panel to other electrical equipment located, for example, in the cover, bag interior or computing unit panel. Also shown is that the display panel prop 27 may, alternatively, be mounted on the cover and extend between the cover and either the display panel or the display panel clasp. Clamping jaws 28a and 28b on the proximal edge of the display panel 2 attach to the attachment flap and pivotally hold the display panel to the cover.

FIG. 78 shows the bag with the cover/display assembly removed. The cover restraining means may be in the form of a restraining storage pocket 85e that both restrains the cover and includes a storage chamber 147 and is attached (for example sewn or riveted) to the bag front wall and/or cover. The pocket may be designed to extend around the outside surface of the cover so that part of the lower portion of the cover is inside the pocket chamber. Part of the pocket may also serve as an attachment flap to pivotally attach the cover to the bag. The pocket may, alternatively, be formed by a permanently attached cover, the bag front and two side restraining sheets forming four sides of the bottom of the chamber. This chamber may be increased in size by shaping the cover and/or pocket and is suitable for storing small objects such as earphones. The pocket may include one or more restraint means attachments 85b (on bag), designed to match restraint means attachments 85c on the cover and restrain the cover at the desired angle (see 85c, FIG. 69B).

1. An electronic display assembly comprising:
a. a bag comprised of an interior and a front wall including a top edge, an outside surface and an inside surface;
b. a display panel comprising a front side including an electronic display, a back side and an attachment edge;
c. one or more free sections connecting the bag to the display panel attachment edge;
d. an extension prop attached to the display panel and extending from the display panel attachment edge; and
e. a vertical operating position prop attached to one of the display panel attachment edge and the extension prop, wherein the vertical operating position prop is configured to extend to the outside surface of the bag front wall and hold the display panel at a viewing angle which may be greater than 180 degrees relative to the outside surface of the bag front wall.

2. The display assembly of claim 1 wherein the free section is comprised of a flexible fabric attachment flap.

3. The display assembly of claim 1 wherein the free section is rigid and is further comprised of a first pivoting attachment connecting the free section to the bag and a second pivoting attachment attaching the free section to the display panel.

4. The display assembly of claim 1 wherein the bag front wall is further comprised of a contact surface configured to aid in temporarily adhering the vertical operating position prop to the bag front wall.

5. The display assembly of claim 1 wherein the display panel is further comprised of camera.

6. The display assembly of claim 1 wherein the display panel is further comprised of a control.

7. The display assembly of claim 6 wherein the control is one of a touch screen on the display and a touch pad located on the back side of the display panel.

8. The display assembly of claim 1, further comprising an electrical connection configured to provide a conduit to electrically connect the display panel to electrical equipment located in the interior of the bag.

9. The display assembly of claim 1, further comprising at least one electrical access opening through a wall of the bag wherein the electrical access opening is configured to pass electrical wiring from the display panel to electrical equipment located in the interior of the bag.

10. The display assembly of claim 1, further comprising a mounting structure on the inside surface of the bag front wall, the mounting structure configured to removably attach a computing unit panel to the inside surface of the bag front wall.

11. The display assembly of claim 1, further comprised of a computing unit panel attached to the inside surface of the front wall.

12. The display panel assembly of claim 11, further comprised of an electrical connection between the display panel and the computing unit panel.

13. The display assembly of claim 1, wherein the vertical operating position prop is pivotable from a storage position to an operating position between the display panel and the outside surface of the bag front wall.

14. The display assembly of claim 1 wherein the extension prop is a prop bar including of a sliding axis part, the sliding axis part slidably attached to the display panel and extendable from the display panel attachment edge.

15. The display assembly of claim 14 wherein the vertical operating position prop is a pivoting arm part attached to the sliding axis part and pivotable to an operating position between the display panel and the outside surface of the bag front wall.

16. The display assembly of claim 1 wherein the free section is attached to the bag at the top edge of the front wall.

17. An electronic display apparatus for pivotally mounting and operating on an outside surface of a bag, the display apparatus comprising:
a. a display panel comprising a front side including an electronic display, a back side and an attachment edge wherein the attachment edge is configured to attach the display panel to one or more free sections of the bag;
b. an extension prop attached to the display panel and extending from the display panel attachment edge; and
c. a vertical operating position prop attached to one of the display panel attachment edge and the extension prop, wherein the vertical operating position prop is configured to extend to the outside surface of the bag front wall and hold the display panel at a viewing angle which may be greater than 180 degrees relative to the outside surface of the bag front wall.

18. The display apparatus of claim 17 wherein the display panel attachment edge includes one or more jaws for attaching to one or more free sections of the bag.

19. The display apparatus of claim 17 wherein the display panel is further comprised of camera.

20. The display apparatus of claim 17 wherein the display panel is further comprised of a control.

21. The display apparatus of claim 20 wherein the control is one of a touch screen on the display and a touch pad located on the back side of the display panel.

22. The display apparatus of claim 17, further comprising an electrical connection configured to provide a conduit to electrically connect the display panel to electrical equipment located in an interior of the bag.

23. The display apparatus of claim 17 wherein the vertical operating position prop is pivotable from a storage position to an operating position between the display panel and the outside surface of a bag front wall.

24. The display assembly of claim 17 wherein the extension prop is a prop bar including of a sliding axis part, the sliding axis part slidably attached to the display panel and extendable from the display panel attachment edge.

25. The display assembly of claim 24 wherein the vertical operating position prop is a pivoting arm part attached to the sliding axis part and pivotable to an operating position between the display panel and the outside surface of the bag front wall.

26. An electronic display apparatus for pivotally mounting and operating on an outside surface of a bag, the display apparatus comprising:
a. a display panel comprising a front side including an electronic display, a back side and an attachment edge wherein the attachment edge is configured to attach the display panel to a flexible fabric attachment flap of the bag; and
b. an extension prop movably attached to the display panel, wherein the extension prop is configured to extend to the outside surface of the bag front wall and hold the display panel at a viewing angle.

27. The display apparatus of claim 26 wherein the extension prop moves slidably on the display panel from a storage position to an operating position between the display panel and the outside surface of the bag front wall.

28. The display apparatus of claim 26 wherein the extension prop moves pivotally near the attachment edge from a storage position to an operating position between the display panel and the outside surface of the bag front wall.

29. The display apparatus of claim 26 wherein the attachment edge is further comprised of one or more jaws configured to attach the display panel to the flexible fabric attachment flap free section.

30. The display assembly of claim 26 wherein the display panel is further comprised of a control.

31. The display assembly of claim 30 wherein the control is one of a touch screen on the display and a touch pad located on the back side of the display panel.
